(19) United States
(12) Patent Application Publication
(10) Pub. No.: US 2026/0072060 A1
(43) Pub. Date: Mar. 12, 2026

(54) DEVICES FOR ANALYZING A SIGNAL AND METHODS THEREOF

(71) Applicant: TECHIFAB GMBH, Dresden (DE)

(72) Inventors: Heidemarie SCHMIDT, Dresden (DE); Horst-Udo HAIN, Dresden (DE); Andreas ERBSLÖH, Krefeld (DE); Martin KIDSZUN, Dresden (DE)

(21) Appl. No.: 19/316,902

(22) Filed: Sep. 2, 2025

(30) Foreign Application Priority Data
Sep. 9, 2024 (DE) 10 2024 125 893.4

(51) Int. Cl. G01R 19/25; G06F 18/213; G06F 18/241

(52) U.S. Cl. CPC G01R 19/2509; G06F 18/213; G06F 18/241

(57) ABSTRACT

A classification device for classifying an electric input signal may include: an input node to receive the electric input signal; a reference circuit configured to generate an electric reference signal; a memristive structure configured to cause an electric response signal as a function of both the electric input signal received at the input node and the electric reference signal generated by the reference circuit; an electric analysis circuit coupled to the memristive structure to determine one or more characteristics of the electric response signal caused by the memristive structure; and one or more processors configured to determine a class associated with the electric input signal based on the one or more characteristics of the electric response signal determined by the electric analysis circuit.

### CROSS-REFERENCE TO RELATED APPLICATION

This patent application claims priority from German Patent Application No. 10 2024 125 893.4 filed on Sep. 9, 2024 according to 35 U.S.C. § 119, the entire disclosure of which is incorporated herein by reference and in its entirety.

### TECHNICAL FIELD

Various aspects relate to a device, e.g., a feature extraction circuit, e.g., a recognition device, for analyzing a signal, e.g., of an electric signal, and methods thereof, e.g., a method for analyzing a signal.

### BACKGROUND

In general, classification may be a process of assigning a specific object to one (or more) of a plurality of classes. By this, the object may be recognized as belonging to the class the object is assigned to. Therefore, classification is a task that may be required for various different kinds of object recognition. An example may be image recognition, where the object is an image or is part of an image. Another example may be measurement data recognition (e.g., data pattern recognition), where the object is measurement data or part of measurement data. A classification model may be employed in order to carry out the classification task. The classification model may be a predictive model configured to predict for a specific (input) object a class of the plurality of classes. Machine learning (ML) classification models (also referred to as ML classifies) may be used for classification tasks due to their high recognition rates (i.e., the rate of correctly classifying an object). Many classification models, such as neural networks, are black-box models that are configured to output the classification result (i.e., the class) responsive to inputting the object without revealing the (inner) relationship between the input and the output. On the other hand, white-box models may allow to observe the relationship between the input and the output (e.g., by means of an observable functional behavior between input and output). Illustratively, white-box models may be transparent (and therefore interpretable), whereas black-box models are considered as being untransparent.

### BRIEF DESCRIPTION OF THE DISCLOSURE

Various aspects relate to a feature extraction device, a recognition and/or classification device, and methods for classifying an electric signal such as a neuro-signal or cardio-signal for example. A device and corresponding methods are described that allow for an analog data processing that allows for a high accuracy and a high recognition rate in particular for classifying electric signal with a comparatively high noise level such as neuro-signals or cardio-signals for example. Alternative technologies for classifying electric signals may be based on neuronal networks that process the signals in digital form. However, it may be not useful to digitalize electric signals in various technical use cases, e.g., if electric signals occur with a low amplitude (e.g., in a voltage range below 1 mV) and in particular in presence of a comparatively high noise level, since an information loss may be associated with a possible digitalization. Furthermore, the analog processing of signals, as described herein, is ultrafast since no signal conversion is necessary for analyzation and determination of one or more parameters that allow for a classification of the electric signal. The recognition device may include a memristive structure to cause a non-linear current output as a function of an applied input signal and a reference input signal.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A and FIG. 1B show various aspects of a feature extraction circuit in a schematic view;

FIG. 1C and FIG. 1D show various aspects of a reference circuit of a feature extraction circuit in a schematic view;

FIG. 1E, FIG. 1F, FIG. 1G, and FIG. 1H show various aspects of a feature extraction of a feature extraction circuit in a schematic view;

FIG. 2A, FIG. 2B, FIG. 2C, FIG. 2D, FIG. 2E, FIG. 2F, FIG. 2G, FIG. 2H, FIG. 2I, and FIG. 2J show various aspects of a processing circuit of a feature extraction circuit in a schematic view;

FIG. 3A, FIG. 3B, and FIG. 3C show various aspects of a recognition device and of a feature extraction circuit in a schematic view;

FIG. 4A, FIG. 4B, FIG. 4C and FIG. 4D show various aspects of a signal processing by a recognition device or by a feature extraction circuit in a schematic view;

FIG. 5A, FIG. 5B, FIG. 5C and FIG. 5D show various aspects of a analyzing signal features extracted by the signal processing by a recognition device or by a feature extraction circuit in a schematic view; and

FIG. 6A, FIG. 6B, FIG. 6C and FIG. 6D show various aspects of a analyzing signal features extracted by the signal processing by a recognition device or by a feature extraction circuit in a schematic view.

### DESCRIPTION

The following detailed description refers to the accompanying drawings that show, by way of illustration, specific details, and aspects in which the invention may be practiced. These aspects are described in sufficient detail to enable those skilled in the art to practice the invention. Other aspects may be utilized and structural, logical, optical, and electrical changes may be made without departing from the scope of the invention. The various aspects are not necessarily mutually exclusive, as some aspects can be combined with one or more other aspects to form new aspects. Various aspects are described in connection with methods and various aspects are described in connection with devices (e.g., arrangements). However, it may be understood that aspects described in connection with methods may similarly apply to the devices, and vice versa.

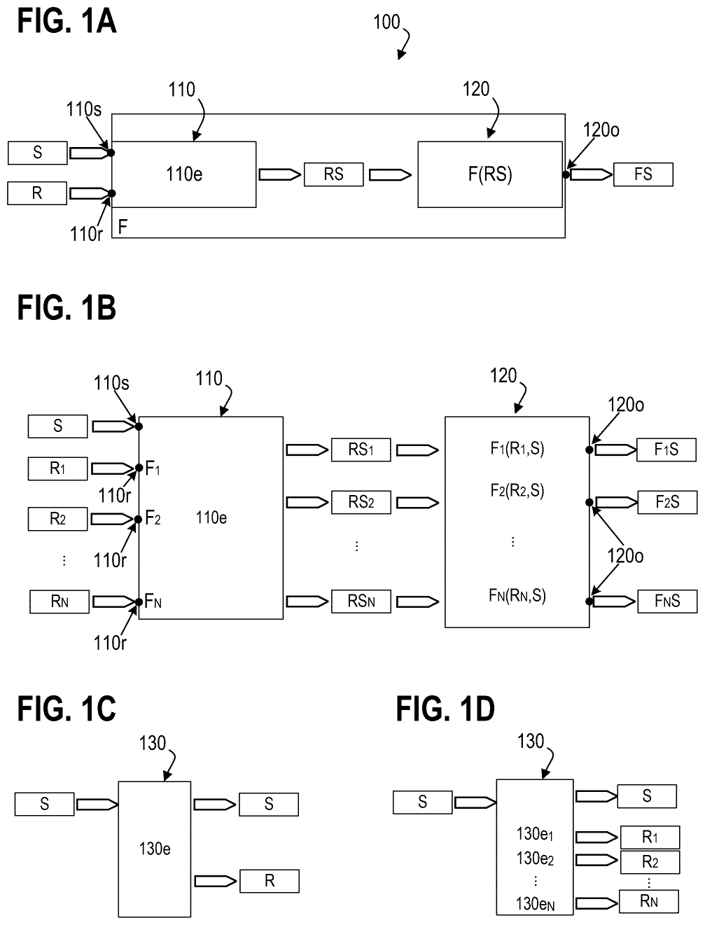

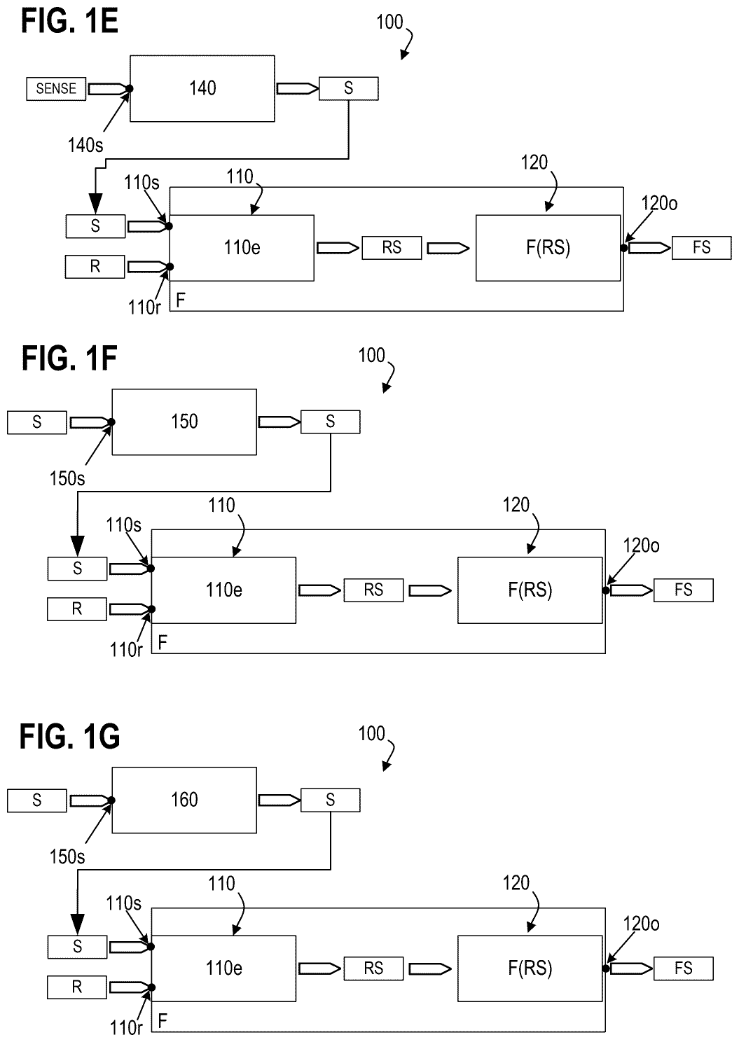

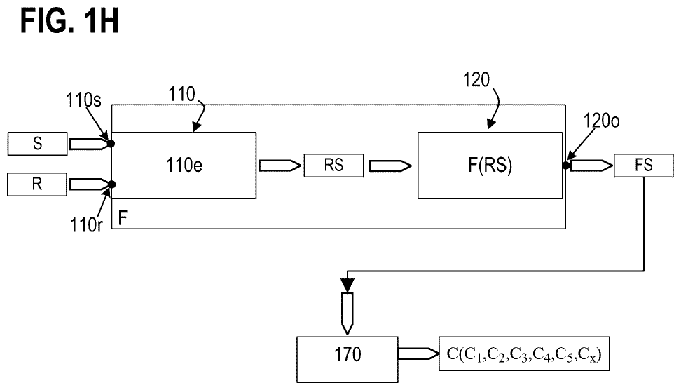

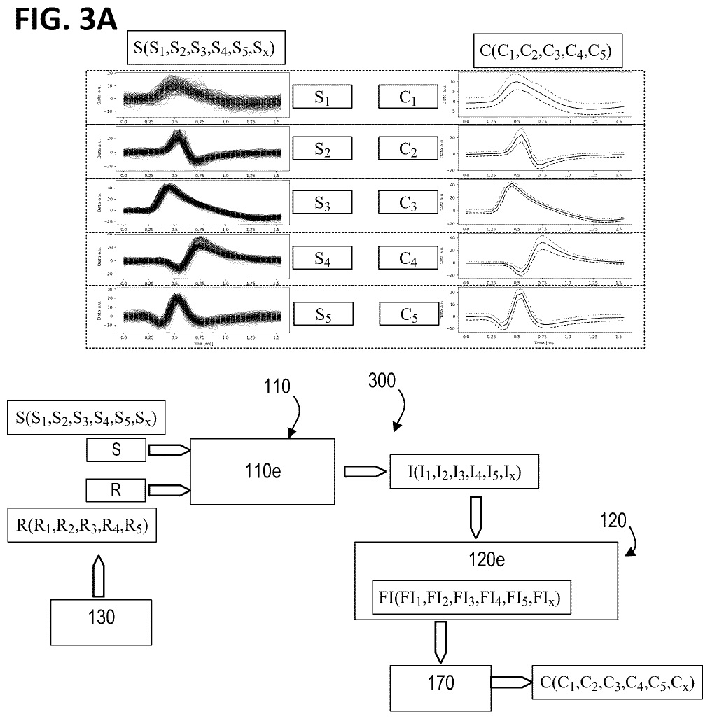

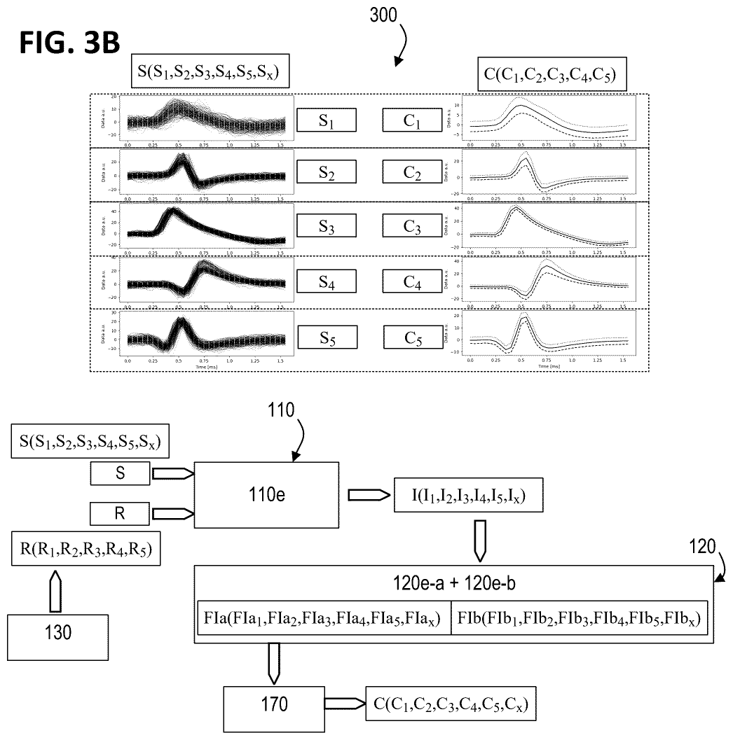

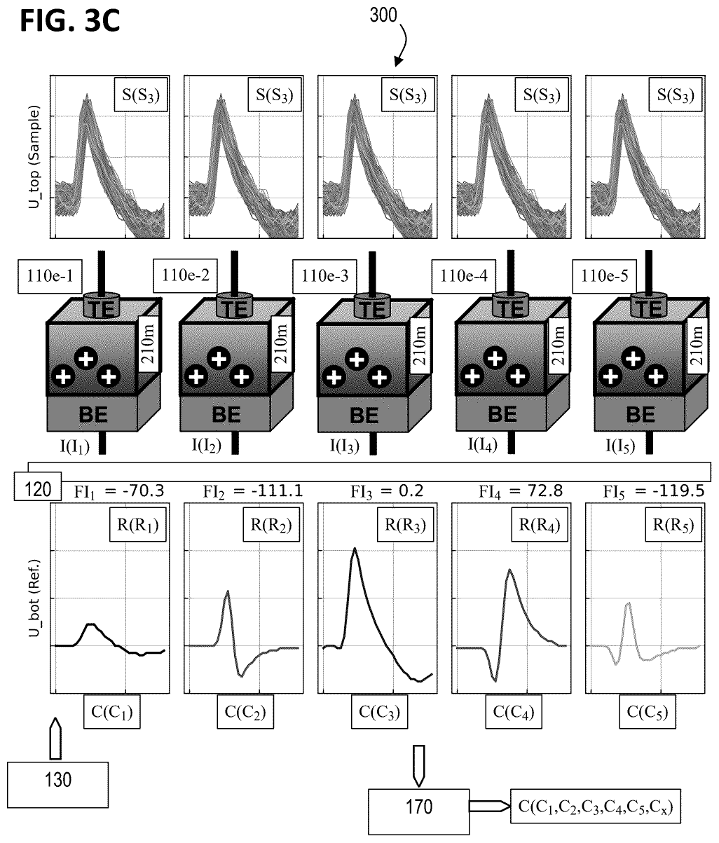

In the following, various aspects related to a feature extraction circuit (e.g., feature extraction circuit 100 as shown in FIG. 1A to 1D) and a recognition device (e.g., recognition device 300 as shown in FIG. 3) are described. The recognition device may be configured to recognize presence and/or absence of specific features within the input signal S. In some aspects, the recognition device may be configured to recognize presence and/or absence of class specific features within the input signal S and to classify the signal into one of a set of classes (also referred to as classification device). In general, feature extraction may be used to identify or classify any type of signal based on features associated with the signal. With reference to electric signals, such as current signals, voltage signals, electromagnetic radiation signals, etc., the features may be specific signal shapes such as sine signal shapes, cosine signal shapes, triangular signal shapes, rectangular signal shapes, dip or kink shapes of the signal, only as examples. In general, a feature could be a similarity of the signal with any type of reference signal, such that the configuration (e.g., the shape) of the reference signal defines the feature and such after a specific check of a signal for this feature a feature value can be determined that represents the similarity of the signal with the reference signal. In the case that the reference signal is associated with a specific class, the similarity of the signal with the reference signal can be used to classify the signal (e.g., to identify the signals as a signal of the specific class). The feature extraction circuit or the recognition device may be used as or may be part of an analysis device for analyzing a signal. The feature extraction circuit or the recognition device may be used as or may be part of a recognition device for recognizing presence of signals of one or more predefined signal types. The feature extraction circuit or the recognition device may be used as or may be part of a classification device for classifying signals into a plurality of classes of signals.

A feature extraction circuit may include, in some aspects, a signal input node to receive an input signal and one or more reference signal input nodes to receive one or more reference signals. The feature extraction circuit may further include a processing circuit configured to cause (e.g., to generate, to create, and/or to output) one or more response signals, each of the one or more response signals being a function of both the input signal received at the input node and one of the one or more reference signals received at the one or more reference signal input nodes. The feature extraction circuit may further include a feature extraction circuit coupled to the processing circuit for analyzing the one or more response signals to cause (e.g., to generate, to create, and/or to output) one or more feature signals representing one or more feature values associated with one or more features of the input signal. The feature extraction circuit may further include an output node to output the one or more feature signals. The feature extraction circuit may optionally further include, in some aspects, a reference circuit configured to branch and modify the received input signal via one or more signal modifiers to cause (e.g., to generate, to create, and/or to output) the one or more reference signals from the input signal.

According to various aspects, the signals (e.g., the input signal(s), the reference signal(s), the response signal(s), feature signal(s), as examples) described herein may be electric input signal s (such as current signals, voltage signals, electromagnetic radiation signals, optical signals, as examples) or any other suitable signals (e.g., sound waves, particle beams, only as examples).

FIG. 1A shows a feature extraction circuit 100 in a schematic view, according to various aspects. The feature extraction circuit 100 may be configured to extract at least one feature F from an input signal S. The feature extraction circuit 100 may include a processing circuit 110 and may be configured to receive the input signal S at a signal input node 110s (e.g., at any suitable terminal, e.g., at a pin, at a contact, only as examples) and to receive a reference signal R at a reference signal input node 110r. The signal input node and/or the reference signal input node may be part of the processing circuit 110 or connected to the processing circuit 110.

The reference signal R may be configured to cause a response signal RS (e.g., a feature specific response signal RS) as a function of the input signal S via the processing circuit. In some aspects the reference signal R is associated with (e.g., defines) the feature F to be extracted from the input signal S. The processing circuit 110 may include at least one processing element 110e (e.g., a load element such as a resistor, a diode, a transistor, a memristor, only as examples) that allows to combine the input signal S and the reference signal R with one another to create the response signal RS based on the combination (e.g., based on an overlay, based on a superimposition, based on a superposition, based on an addition, based on a subtraction, only as examples) of the input signal S and the reference signal R.

The feature extraction circuit 100 may further include an analysis circuit 120 and may be configured to output a feature signal FS at an output node 120o (e.g., at any suitable terminal, e.g., at a pin, at a contact, only as examples). The output node 120o may be part of the analysis circuit 120 or connected to the analysis circuit 120. The analysis circuit 120 may be configured to receive the response signal RS to determine a feature value F(RS) based on the received response signal RS and to cause (e.g., to generate, to create, and/or to output) the feature signal FS representing the feature value F(RS). A feature value may be a value associated with the feature signal FS at a predefined time (e.g., at an end of a features signal integration time).

The feature value F(RS) is a function of the response signal RS, since the feature value F(RS) is obtained from the response signal RS via the analysis circuit 120. The response signal RS in turn is a function of the input signal S and the reference signal R and the processing thereof via the processing circuit 110. Therefore, the feature value F(RS) is associated with a feature F defined by the reference signal R and the processing of the input signal S with the reference signal R via the processing circuit. The feature signal FS that is provided at the output node 120o represents the feature value F(RS) of a processed input signal and can be utilized for further processing, e.g., for a classification of the input signal S, for monitoring the input signal S.

The feature extraction circuit 100 illustrated in FIG. 1A is in a configuration, wherein a single reference signal R is used to generate a single response signal RS. The analysis circuit 120 may be configured to cause (e.g., to generate, to create, and/or to output) a single feature signal FS representing a single feature value determined from the single response signal RS. However, in other aspects, the analysis circuit 120 may be configured to cause (e.g., to generate, to create, and/or to output) a set of feature signal FS representing a set of feature values determined from the single response signal RS. Only as an example, the analysis circuit 120 may be configured to determine a time integral value from a physical property (e.g., current, voltage, only as examples) of the single response signal RS during a time interval to determine a single feature value or during a set of distinct time intervals to determine a set of feature values from the single response signal RS. In other aspects, the analysis circuit 120 may be configured to determine and output the feature value F(RS) as a relative value by obtaining at least two auxiliary feature values from the single response signal RS and by determining a ratio of the at least two auxiliary feature values as the basis for the output of the feature value F(RS).

In other aspects, as illustrated in FIG. 1B, the feature extraction circuit 100 may be in a configuration wherein two or more reference signals R₁, R₂, . . . , R_{N} are used to define two or more features F₁, F₂, . . . , F_{N} and to generate two or more response signals RS₁, RS₂, . . . , RS_{N} based on the input signal S and the two or more reference signals R₁, R₂, . . . , R_{N}. As explained above, at least one feature value F₁(R₁,S), F₂(R₂,S), . . . , F_{N}(R_{N},S) can be determined based on each of the two or more (e.g., a number of N) response signals RS₁, RS₂, . . . , RS_{N}. The two or more feature values F₁(R₁,S), F₂(R₂,S), . . . , F_{N}(R_{N},S) may be represented by two or more feature signals F₁S, F₂S, . . . , FNS to be output.

It is understood that the number of reference signal input nodes and output nodes is selected accordingly with the number of reference signals used and the desired number of feature signals to be used for a further processing of the desired number of feature values.

According to various aspects, the feature extraction circuit 100 may include a processing circuit 110 and an analysis circuit 120. The processing circuit 110 is configured to receive both the input signal S and the reference signal R. The processing circuit 110 is configured to generate and output a response signal RS based on a processing of both the input signal S and the reference signal R. Illustratively, the response signal RS is provided as a function of both the input signal S and the reference signal R. The electric analysis circuit 120 is configured to receive the electric response signal RS and to determine a feature value F(RS) associated with the input signal S from the electric response signal RS. The electric analysis circuit 120 is further configured to output a feature signal FS representing the (determined) feature value F(RS) associated with the presence (e.g., presence or absence) of the feature F in the input signal S.

According to various aspects, the reference signal R is associated with the feature F to be determined from the input signal S. In some aspects, the reference signal R is configured to define the feature F to be determined from the input signal S. The reference signal R is, in various aspects, utilized in the feature extraction circuit 100 to extract a desired feature F from the input signal S by processing both the reference signal R and the input signal S via the one or more processing elements 110e of the processing circuit 110. In some aspects, the feature F may include a similarity of the input signal S with the reference signal R, and the processing of both the input signal S and the reference signal R may include a modification of the input signal S based on the reference signal R, e.g., the processing of both the input signal S and the reference signal R may include a combination (e.g., a superposition) of the input signal S and the reference signal R with one another.

According to various aspects, the input signal S may include an electric analog input signal such as an analog voltage input signal (US) or an analog current input signal (IS), for example. According to various aspects, the reference signal R may include an electric analog reference signal such as an analog voltage reference signal (UR) or an analog current reference signal (IR), for example. According to various aspects, the response signal RS may include an electric analog response signal such as an analog voltage response signal (URS) or an analog current response signal (IRS), for example. The one or more processing elements 110e for processing (e.g., modification, super positioning, for example) the input signal S and the reference signal R may include at least one of the following analog electronic components: a resistor, a diode, a memristor. In general, the one or more processing elements 110e may include one or more electronic components with a linear current/voltage characteristic (e.g., one or more electronic components with ohmic behavior) such as a resistor. However, feature extraction may be enhanced, as described further below, if the one or more processing elements 110e exhibit a non-linear current/voltage characteristic (e.g., one or more electronic components with non-ohmic behavior) such as a diode or a memristor. In the case that one or more memristors are used as processing elements 110e for the feature extraction, the feature extraction results may be enhanced due to the wide range of non-linearity provided by the one or more memristors (e.g., by one or more analog barrier switching memristors). Some aspects of an analog barrier switching memristor are described with reference to FIG. 3C.

In some aspects, the feature extraction circuit 100 (e.g., the analysis circuit 120) is configured to operate time interval based to determine a set of feature values associated with a respective operation time interval. Therefore, a variable input signal can be analyzed time interval based via the feature extraction circuit 100 such that a quasi continuous operation can be realized. In an application, a sensor output can be connected to the input node of the feature extraction circuit 100 and the feature extraction circuit 100 can be configured to monitor the sensor output with respect to an output of predefined types of sensor signals. As an example, depending on the reference signal, the sensor output can be monitored for presence of a specific sensor signal (e.g., defined by the shape of the signal).

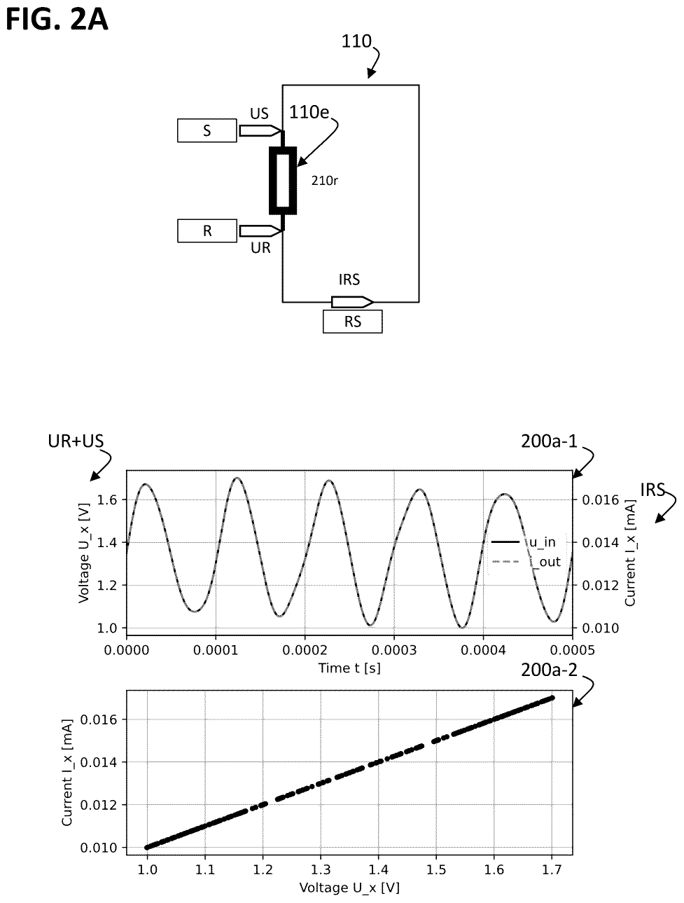

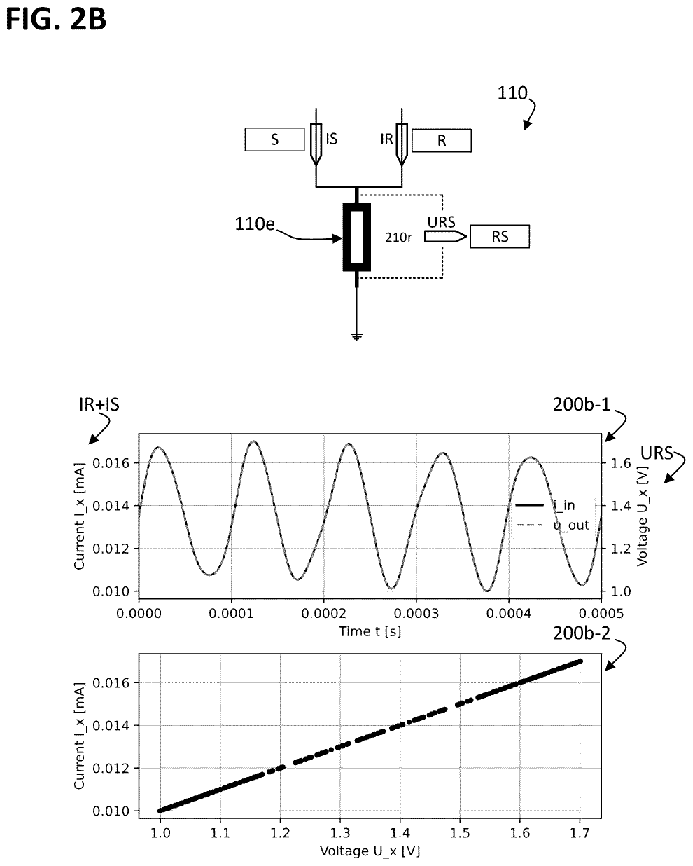

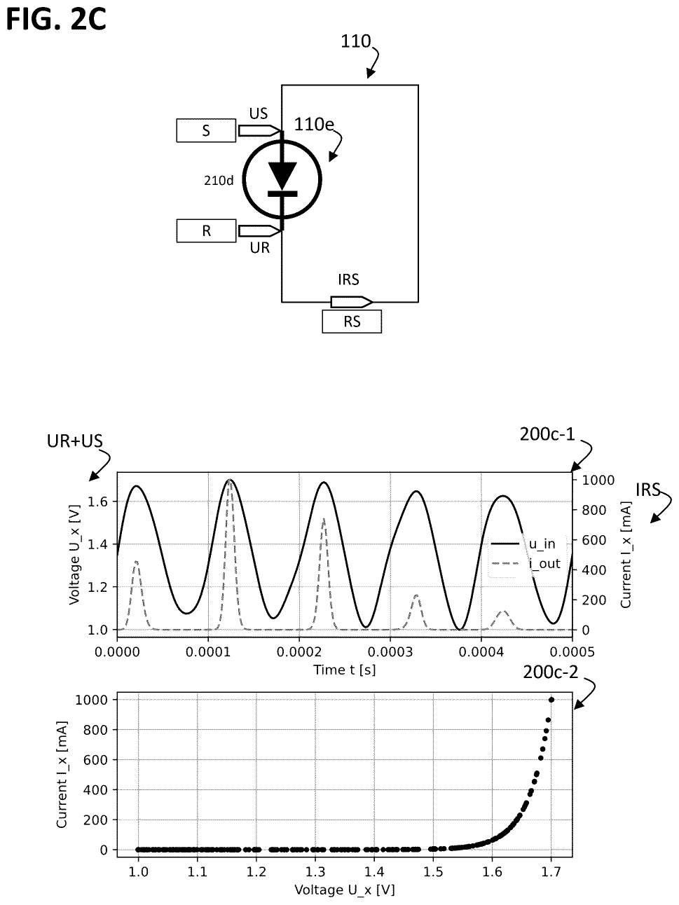

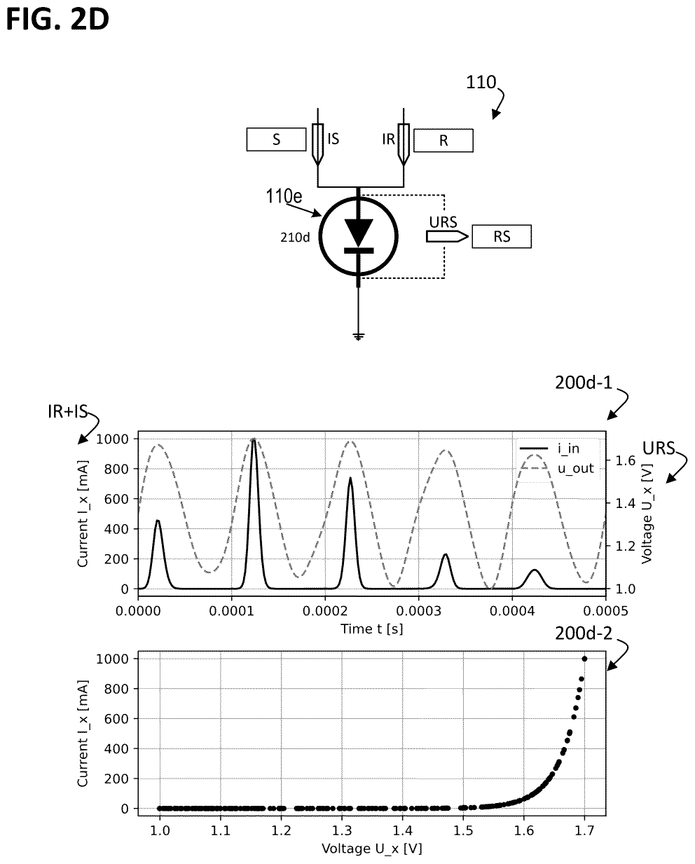

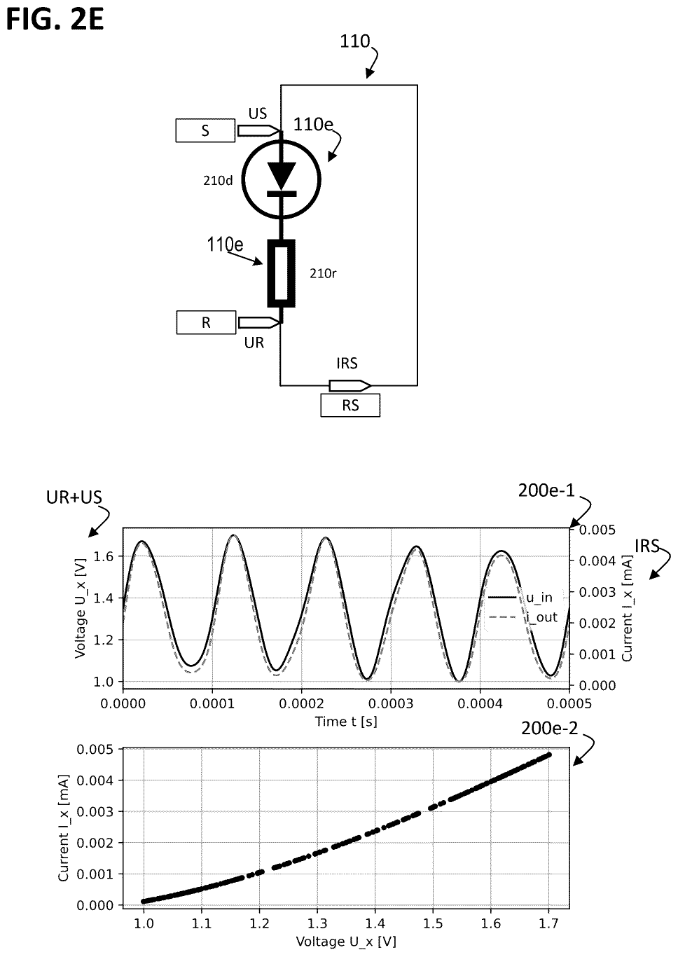

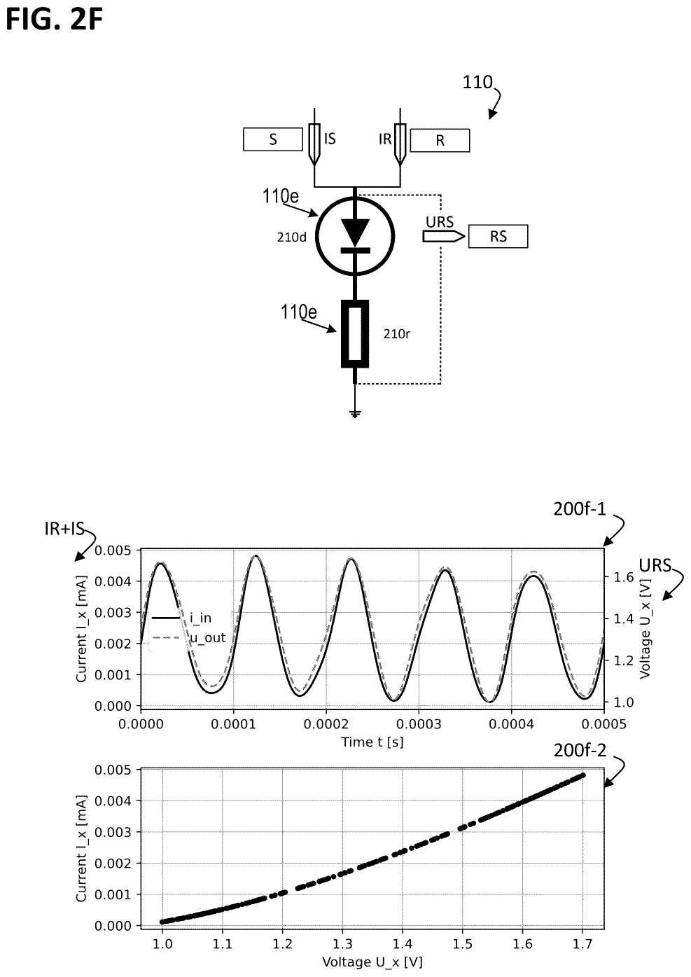

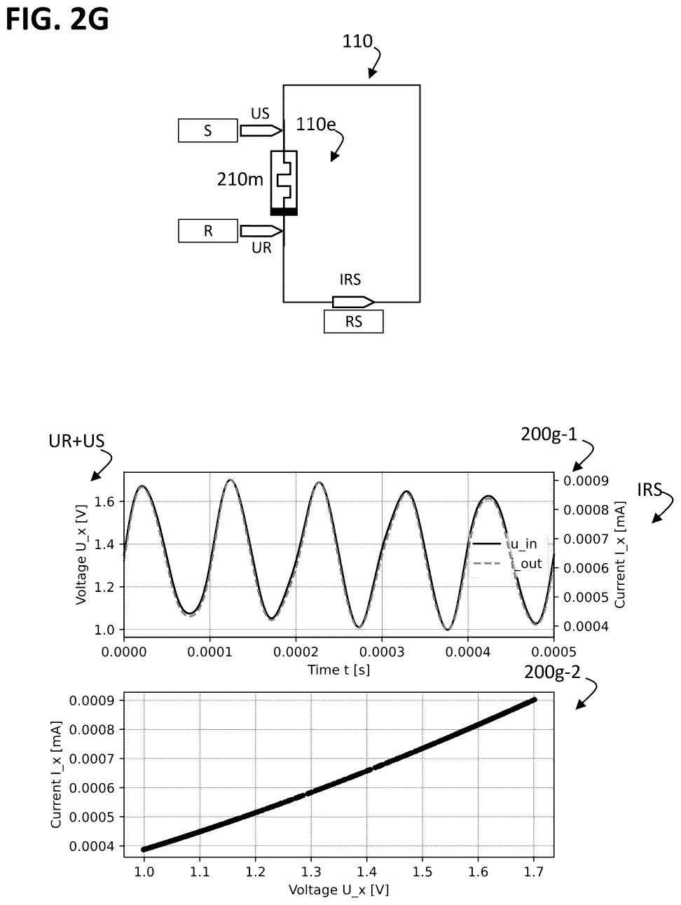

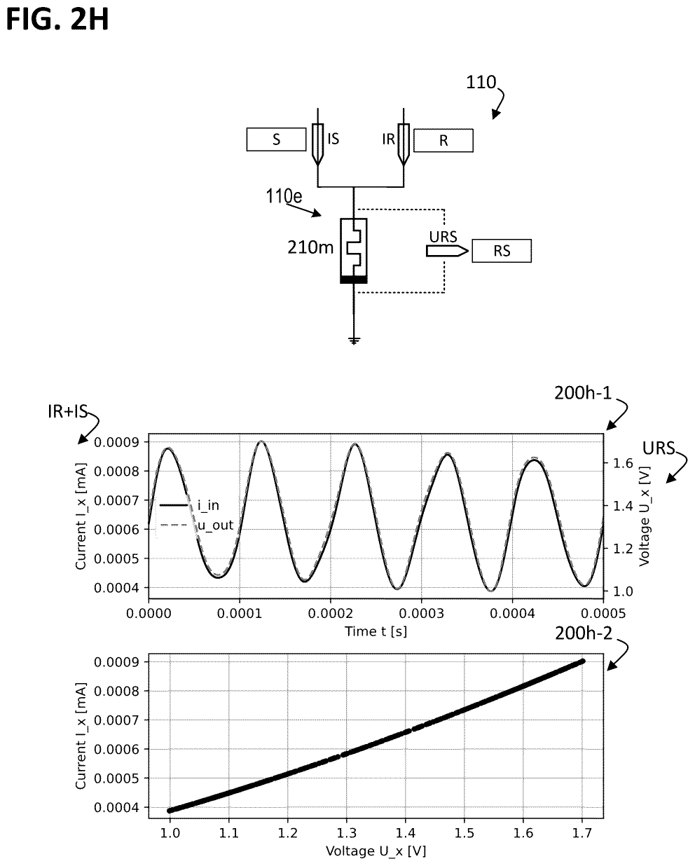

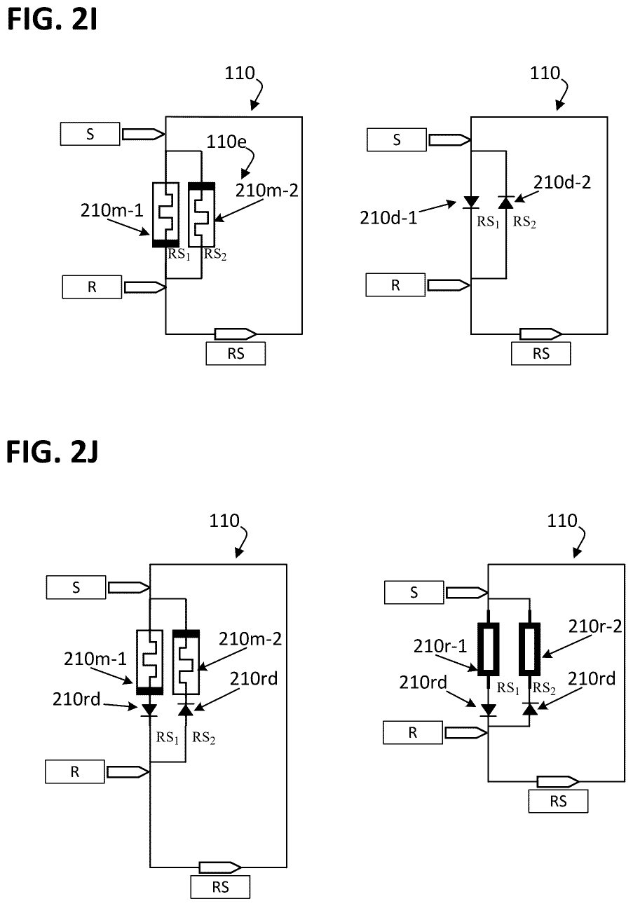

Various aspects of a processing of both the reference signal R and the input signal S via one or more processing elements 110e (e.g., one or more electronic components of the feature extraction circuit 100) are described in more detail with reference to FIGS. 2A to 2H.

According to various aspects, the feature extraction circuit 100 may include a reference circuit 130. The reference circuit 130 may be configured to generate, for example, a plurality of class specific reference signals to classify the input signal. The reference circuit 130 may be configured to generate, for example, a plurality of class specific reference signals having class specific signal shapes to classify various signal shapes of the input signal. The class specific reference signals may be determined based on test measurements (e.g., similar to a training) using test signals as input signals, wherein the class specific reference signals are varied to increase the efficiency of the classification (e.g., the reach a predefined recognition rate).

In general, a timing of the signals may be needed to combine a signal and a reference signal, e.g., in terms of a superposition the respective signal shapes and to identify specific signal shapes as described herein. However, in some aspects, the feature extraction circuit 100 may include a reference circuit 130 that is configured to branch the reference signals from the input signal itself, as illustrated in FIG. 1C and FIG. 1D. This causes a correct timing of its own and may allow for a reduction of circuit complexity, since, for example, no event detection and signal timing is to be implemented.

According to various aspects, the reference circuit 130 may be configured to branch (illustratively to provide a duplicate) the received input signal S. The reference circuit 130 may be configured to modify the branched (e.g., duplicated) input signal via one or more signal modifier elements 130e, 130e₁, 130e₂, . . . , 130e_{N} to cause (e.g., to generate, to create, and/or to output) the one or more reference signals R, R₁, R₂, . . . , R_{N}. In this configuration, the one or more signal modifier elements 130e, 130e₁, 130e₂, . . . , 130e_{N} are configured to define the one or more reference signals (e.g., the reference signal shape, the reference signal amplitude, the reference signal offset, the reference signal delay with respect to the input signal, only as examples). Illustratively, the one or more signal modifier elements 130e, 130e₁, 130e₂, . . . , 130e_{N} defined tuning parameter to cause distinct (e.g., class specific) reference signals R, R₁, R₂, . . . , R_{N}. The tuning parameter (e.g., the specific configuration of the one or more signal modifier elements 130e, 130e₁, 130e₂, . . . , 130e_{N}) may be determined based on test measurements (e.g., similar to a training) using test signals as input signals, wherein the class specific reference signals are varied to increase the efficiency of the classification (e.g., the reach a predefined recognition rate).

In other aspects, as illustrated in FIG. 1E, the feature extraction circuit 100 may further include a sensor signal input node 140s to receive a sensor signal, SENSE. The sensor signal input node 140s may be connected to or part of a mapping circuit 140 included in the feature extraction circuit 100 or coupled to the feature extraction circuit 100. The mapping circuit 140 may be configured to modify (e.g., level shift, e.g., amplify, as examples) the sensor signal to provide the input signal S within in a predefined signal range. The predefined signal range may be associated with an operation of the one or more processing elements 110e of the processing circuit 110 for processing the input signal S. The mapping of the sensor signal into a predefined signal range may allow for a processing of the signal in an operation range of the processing elements 110e. As an example, a diode may operate in a voltage range from −2 V to +2 V and a memristor may operate in a positive voltage range from +1 V to +10 V for example, and therefore, an sensor signal that is within another voltage range can be mapped to the operation voltage range of the diode or the memristor, only as an example.

In some aspects, the sensor signal, SENSE, may be an analog signal and the input signal may be an analog input signal. In other aspects, the sensor signal, SENSE, may be a digital sensor signal; however, the input signal may be an analog input signal. Therefore, the mapping circuit 140 may be configured to convert a digital sensor signal into an analog input signal (S).

In other aspects, as illustrated in FIG. 1F, the feature extraction circuit 100 may further include an input delay circuit 150 configured to delay the input signal S received at the input node 110s or configured to delay the input signal S provided to the input node 110s. In some aspects, e.g., in the case that the one or more reference signals R are generated by a dedicated signal generator alternatively to branching the one or more reference signals R from the input signal S, the input signal S may be synchronized with the one or more reference signals R for the processing of the signals S, R in the processing circuit 110.

In other aspects, as illustrated in FIG. 1G, the feature extraction circuit 100 may further include an event detector circuit 160 configured to detect reception of the input signal S (e.g., if the input signal is a non-continuous signal with time dependent signal peaks of various types) at the input node 110s. The event detector circuit 160 may be configured to control an operation of the processing circuit 110, the analysis circuit 120, and/or the reference circuit 130 based on a detected reception. In some aspects, e.g., in the case that the one or more reference signals R are generated by a dedicated signal generator alternatively to branching the one or more reference signals R from the input signal S, the input signal S may be synchronized with the one or more reference signals R for the processing of the signals S, R in the processing circuit 110, wherein the event detector circuit 160 is configured to determine a time at which the input signal S is feed into the processing circuit 110 and trigger the generation of the one or more reference signals R and/or trigger the feeding of the one or more reference signals R into the processing circuit 110 based on the determined time. In some aspects, the control of an operation influenced by the event detector circuit 160 may include activating the processing circuit 110; and/or delaying the input signal S; and/or activating the analysis circuit 120; and/or resetting one or more signal integrators; and/or activating the reference circuit 130; and/or modifying and/or triggering the reference signal R generated by the reference circuit 130.

In some aspects, the generation of the feature signal FS by the analysis circuit 120 may be based on a time integration of the respective response signal RS during a predefined time interval. Therefore, the time integration may need a reset of the integrator, wherein the reset can be controlled by the analysis circuit 120 based on a signal provided from the event detector. Therefore, in some aspects, the time integration may start as a response of a detected event (e.g., based on a detected arrival of a signal pulse of the input signal at the input node 110s of the processing circuit 110).

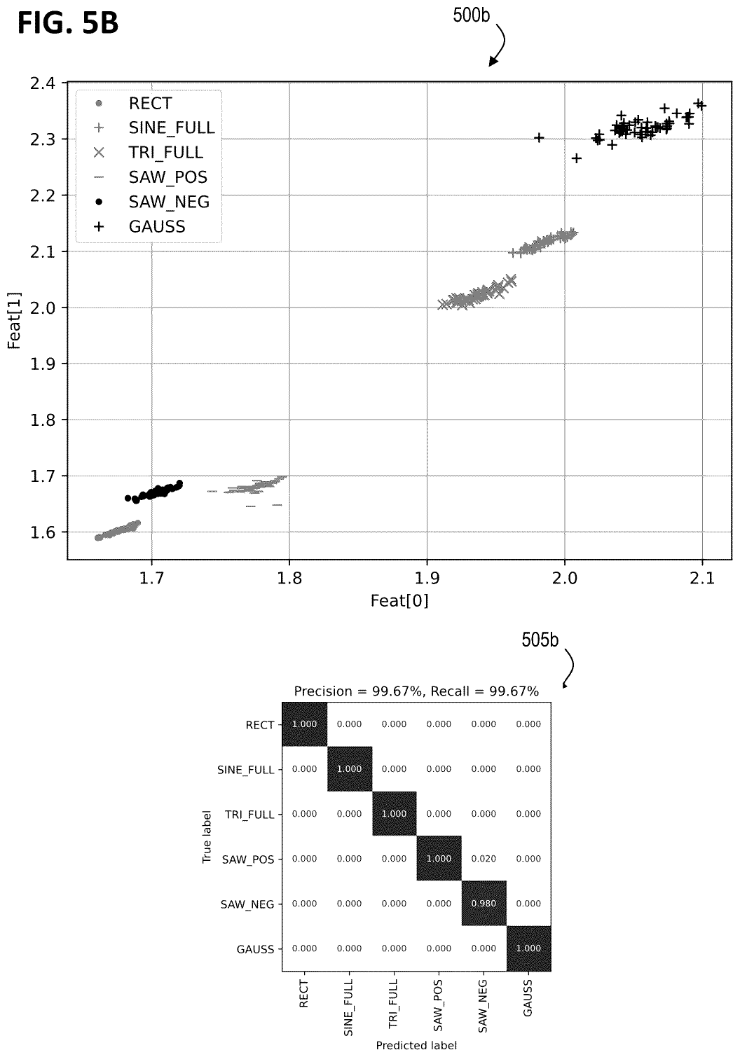

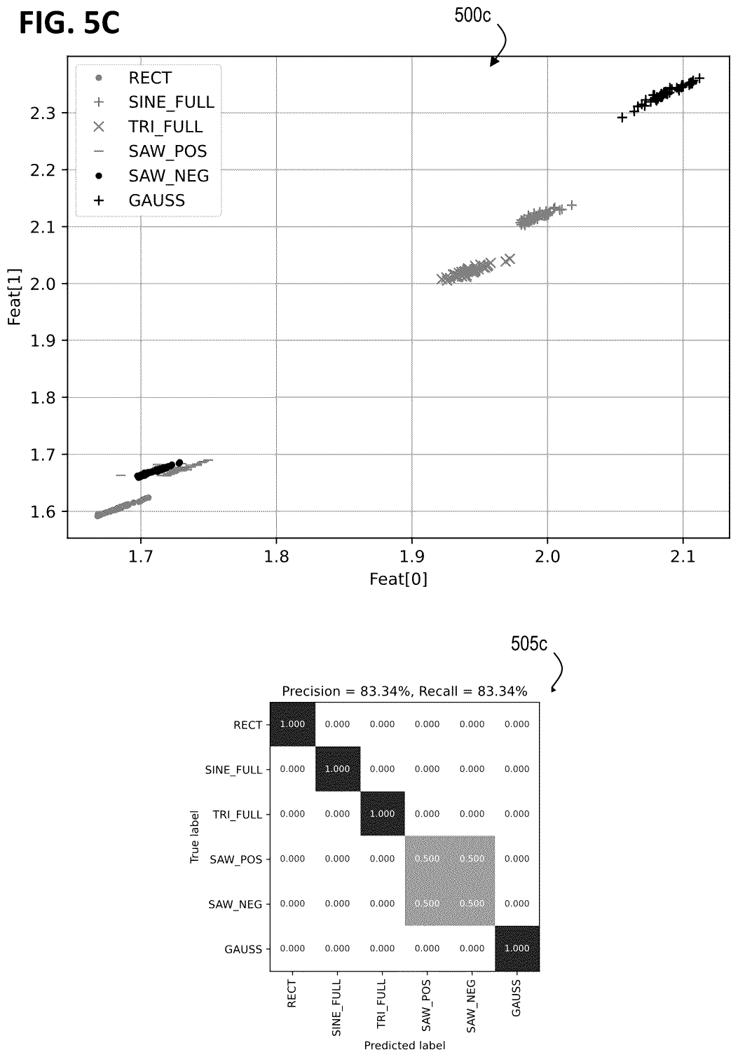

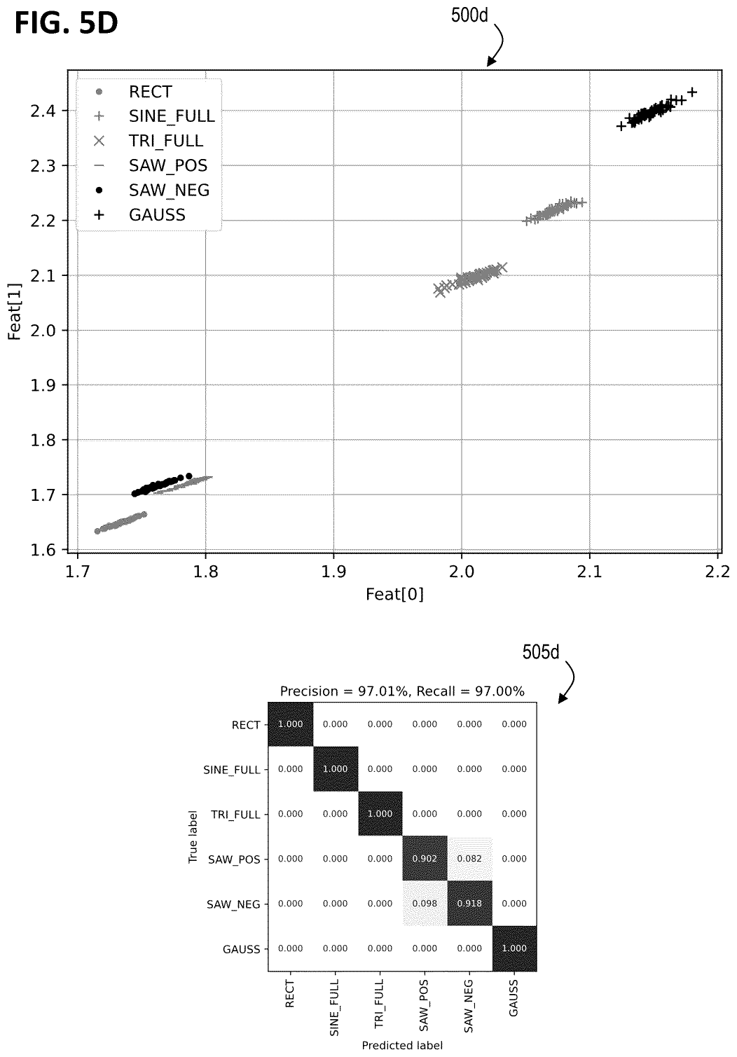

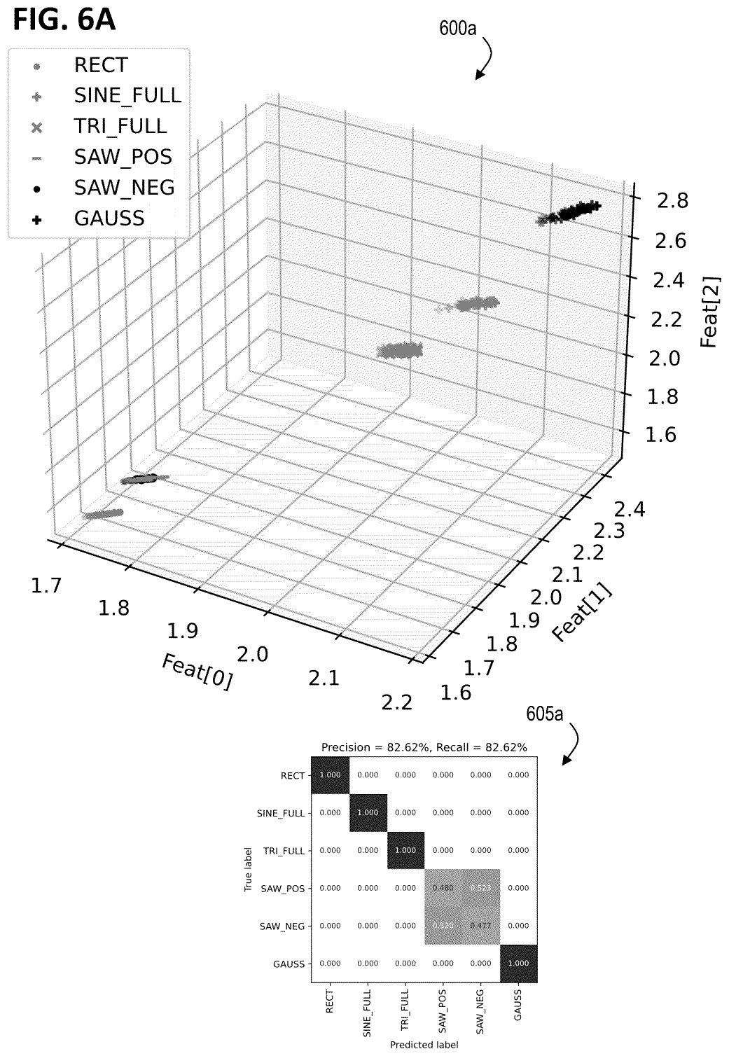

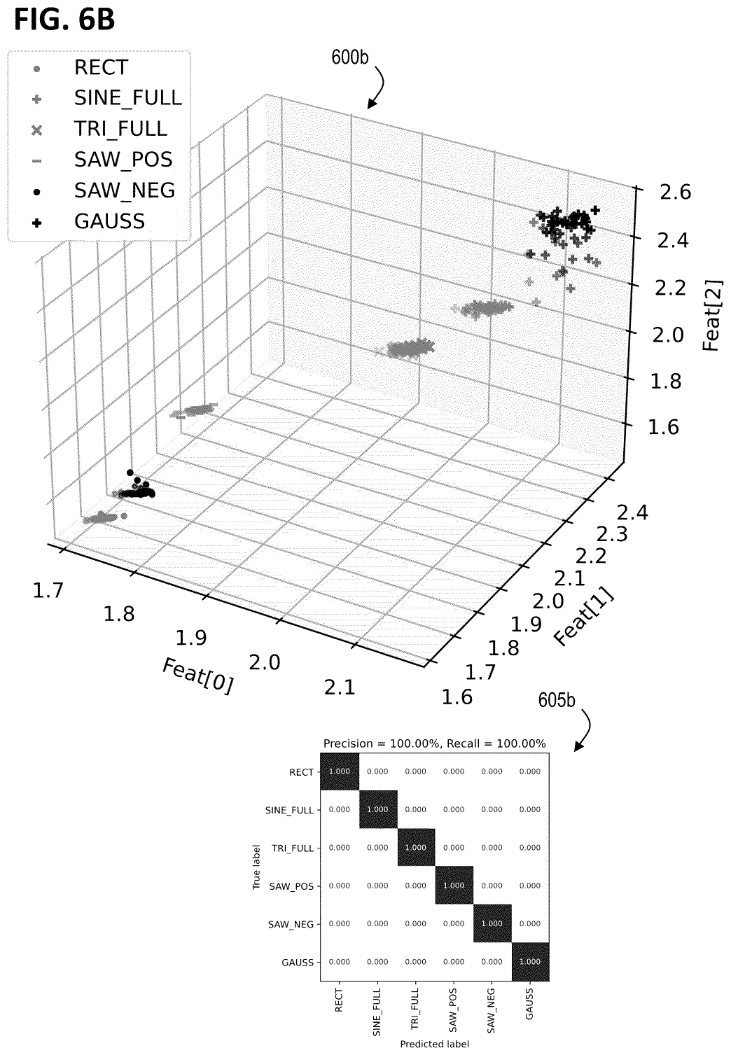

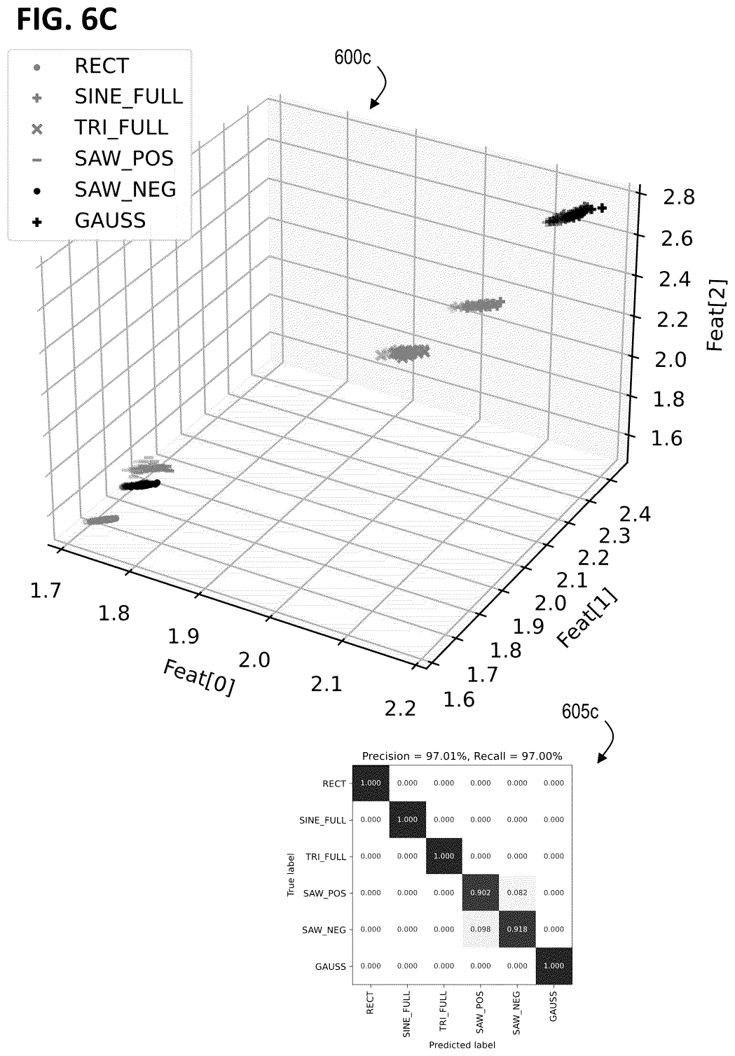

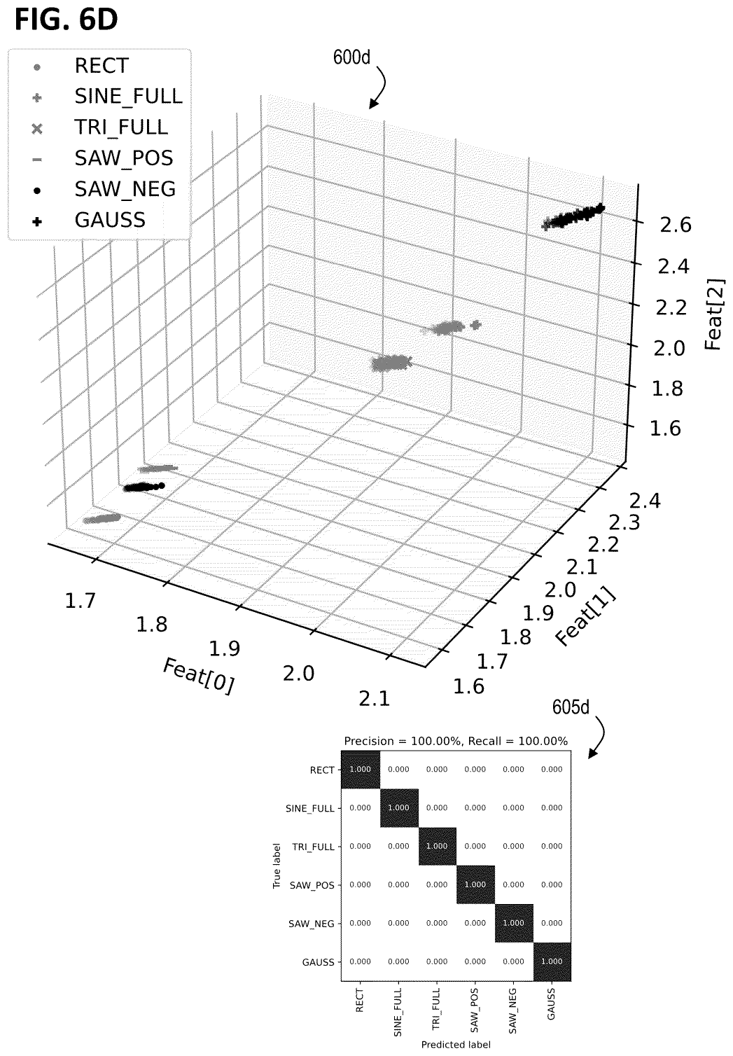

In other aspects, as illustrated in FIG. 1H, the feature extraction circuit 100 may further include one or more processors 170 configured to determine a class C associated with the input signal S based on the one or more feature signals FS (see also classes C₁, . . . , C_{N} as described further below, e.g., with reference to FIG. 3A to FIG. 3C). In some aspects, the one or more processors 170 may be configured to determine a respective class C associated with the input signal S based on analyzing one or more feature values (e.g., electric current values, voltage values, relative ratios of electric current and/or voltage values, as examples) of the one or more feature signals F. In some aspects, the one or more processors 170 may be configured to determine the respective class C associated with the input signal S based on clustering one or more feature values of the one or more feature signals FS in an n-dimensional feature space (see, for example, FIG. 5A to FIG. 5D and FIG. 6A to FIG. 6D).

FIG. 2A and FIG. 2B illustrate a response behavior of a processing element 110e of a processing circuit 110, according to various aspects described herein with reference to the feature extraction circuit 100. In some aspects, the processing of the input signal S and the reference signal R is carried out by applying these two signals directly to the processing element 110e of the processing circuit 110 to thereby cause a response signal RS that is a function of both the input signal S and the reference signal R. The diagrams 200a-1, 200a-2 show the current/voltage behavior of the processing circuit 110 for the case that the processing element includes a resistor 210r or other one or more electronic components with resistor-like (e.g., linear current/voltage) behavior for a conversion of the input/reference signals S, R into a response signal RS.

In some aspects, the input signal S is supplied to the processing element 110e (e.g., to the resistor 210r shown in FIG. 2A) as a voltage input signal US and the reference signal R is supplied to the processing element 110e (e.g., to the resistor 210r shown in FIG. 2A) as a voltage reference signal UR and the processing via the processing element 110e (e.g., the resistor 210r shown in FIG. 2A) generates a current response signal IRS as the resulting response signal RS according to ohm's law in the processing circuit 110 (shown in FIG. 2A). The processing circuit 110 may be configured to process voltage controlled input and reference signals (US, UR) and cause a current controlled response signal (IRS). The diagrams 200a-1, 200a-2 show the current/voltage behavior of the resistor 210r for a forced voltage input and a current response.

In a similar way, the processing circuit 110 may be configured to process current controlled input and reference signals (IS, IR) and a voltage controlled response signal (URS), as shown exemplarily for the processing circuit 110 in FIG. 2B with diagrams 200b-1, 200b-2. The diagrams 200b-1, 200b-2 show the current/voltage behavior of the resistor 210r for a forced current input and a voltage response.

FIG. 2C and FIG. 2D illustrate a response behavior of a processing element 110e of a processing circuit 110, according to various aspects described herein with reference to the feature extraction circuit 100. In some aspects, the processing of the input signal S and the reference signal R is carried out by applying these two signals directly to the processing element 110e of the processing circuit 110 to thereby cause a response signal RS that is a function of both the input signal S and the reference signal R. The diagrams 200c-1, 200c-2 show the current/voltage behavior of the processing circuit 110 for the case that the processing element includes a diode 210d or other one or more electronic components with diode-like (e.g., non-linear) current/voltage behavior for a conversion of the input/reference signals S, R into a response signal RS.

In some aspects, the input signal S is supplied to the processing element 110e (e.g., to the diode 210d shown in FIG. 2C) as a voltage input signal US and the reference signal R is supplied to the processing element 110e (e.g., to the diode 210d shown in FIG. 2C) as a voltage reference signal UR and the processing via the processing element 110e (e.g., the diode 210d shown in FIG. 2C) generates a current response signal IRS as the resulting response signal RS according to ohm's law in the processing circuit 110 (shown in FIG. 2C). The processing circuit 110 may be configured to process voltage controlled input and reference signals (US, UR) and cause a current controlled response signal (IRS). The diagrams 200c-1, 200c-2 show the current/voltage behavior of the diode 210d for a forced voltage input and a current response.

In a similar way, the processing circuit 110 may be configured to process current controlled input and reference signals (IS, IR) and a voltage controlled response signal (URS), as shown exemplarily for the processing circuit 110 in FIG. 2D with diagrams 200d-1, 200d-2. The diagrams 200d-1, 200d-2 show the current/voltage behavior of the diode 210d for a forced current input and a voltage response.

FIG. 2E and FIG. 2F illustrate a response behavior of a processing element 110e of a processing circuit 110, according to various aspects described herein with reference to the feature extraction circuit 100. In some aspects, the processing of the input signal S and the reference signal R is carried out by applying these two signals directly to one or more processing elements 110e of the processing circuit 110 to thereby cause a response signal RS that is a function of both the input signal S and the reference signal R. The diagrams 200e-1, 200e-2 show the current/voltage behavior of the processing circuit 110 for the case that the processing elements includes a diode 210d and a resistor 210r or other one or more electronic components with resistive-diode-like (e.g., non-linear) current/voltage behavior for a conversion of the input/reference signals S, R into a response signal RS.

In some aspects, the input signal S is supplied to the processing elements 110e (e.g., to a series connection of the diode 210d and the resistor 210r shown in FIG. 2E) as a voltage input signal US and the reference signal R is supplied to the processing elements 110e (e.g., to the series connection of the diode 210d and the resistor 210r shown in FIG. 2E) as a voltage reference signal UR and the processing via the processing elements 110e (e.g., the series connection of the diode 210d and the resistor 210r shown in FIG. 2E) generates a current response signal IRS as the resulting response signal RS according to ohm's law in the processing circuit 110 (shown in FIG. 2E). The processing circuit 110 may be configured to process voltage controlled input and reference signals (US, UR) and cause a current controlled response signal (IRS). The diagrams 200e-1, 200e-2 show the current/voltage behavior of the series connection of the diode 210d and the resistor 210r for a forced voltage input and a current response.

In a similar way, the processing circuit 110 may be configured to process current controlled input and reference signals (IS, IR) and a voltage controlled response signal (URS), as shown exemplarily for the processing circuit 110 in FIG. 2F with diagrams 200f-1, 200f-2. The diagrams 200f-1, 200f-2 show the current/voltage behavior of the series connection of the diode 210d and the resistor 210r for a forced current input and a voltage response.

FIG. 2G and FIG. 2H illustrate a response behavior of a processing element 110e of a processing circuit 110, according to various aspects described herein with reference to the feature extraction circuit 100. In some aspects, the processing of the input signal S and the reference signal R is carried out by applying these two signals directly to one or more processing elements 110e of the processing circuit 110 to thereby cause a response signal RS that is a function of both the input signal S and the reference signal R. The diagrams 200g-1, 200g-2 show the current/voltage behavior of the processing circuit 110 for the case that the processing element includes a memristor 210m (e.g., a barrier switching memristor) or other one or more electronic components with memristor-like (e.g., non-linear) current/voltage behavior for a conversion of the input/reference signals S, R into a response signal RS.

In some aspects, the input signal S is supplied to the processing element 110e (e.g., to the memristor 210m shown in FIG. 2G) as a voltage input signal US and the reference signal R is supplied to the processing element 110e (e.g., to the memristor 210m shown in FIG. 2G) as a voltage reference signal UR and the processing via the processing element 110e (e.g., the memristor 210m shown in FIG. 2G) generates a current response signal IRS as the resulting response signal RS according to ohm's law in the processing circuit 110 (shown in FIG. 2G). The processing circuit 110 may be configured to process voltage controlled input and reference signals (US, UR) and cause a current controlled response signal (IRS). The diagrams 200g-1, 200g-2 show the current/voltage behavior of the memristor 210m for a forced voltage input and a current response.

In a similar way, the processing circuit 110 may be configured to process current controlled input and reference signals (IS, IR) and a voltage controlled response signal (URS), as shown exemplarily for the processing circuit 110 in FIG. 2H with diagrams 200h-1, 200h-2. The diagrams 200h-1, 200h-2 show the current/voltage behavior of the memristor 210m for a forced current input and a voltage response.

FIG. 2I and FIG. 2J show various schematic views of the processing circuit 110 configured to process positive and negative signal portions independently (e.g., distinct) from one another. In some aspects, the processing circuit 110 may include an anti-parallel connection of two memristors 210m-1, 210m-2 or an anti-parallel connection of two diodes 210d-1, 210d-2 (or a parallel or antiparallel connection of other electronic components with a non-linear current/voltage behavior) as processing elements 110e for the processing of the signals. Optionally, rectifying diodes 210rd and one or more additional processing elements can be used to divide the signal into a positive signal processed by one or more first processing elements (e.g., a memristor 210m-1, e.g., a resistor 210r-1) and into a negative signal processed by one or more second processing element (e.g., a memristor 210m-2, e.g., a resistor 210r-2), as illustrated in FIG. 2J. The response RS caused by the processing circuit 110 is a result of both, the first response RS₁ of the first processing element (e.g., memristor 210m-1, diode 210d-1, resistor 210r-1) and the second response RS₂ of the second processing element (e.g., memristor 210m-2, diode 210d-2, resistor 210r-2) due to the parallel connection. Such configurations allow for a distinct processing of negative and positive parts of the input signal S and/or of the super positioned reference signal R.

According to various aspects, a recognition device may be configured to classify a signal S into a class C in according with presence of a predefined (e.g., class-specific) signal shape. In a similar way, the signal S may be at least identified as a signal of a specific signal type to determined, for example, presence of a specific state associated with the specific signal type, e.g., in a monitoring application.

FIG. 3A, FIG. 3B, and FIG. 3C illustrate an operation principle of feature extraction and an implementation of a recognition device 300, as explained herein according to various aspects. The signal S(S₁, S₂, S₃, S₄, S₅, Sₓ) may have, e.g., in certain time intervals, a signal shape S of any one of a plurality of signal shapes S₁, S₂, S₃, S₄, S₅, Sₓ. The signal shapes S₁, S₂, S₃, S₄, S₅, Sₓ may include (only as an example) signal shapes S₁ of a first class C₁ of signal shapes, signal shapes S₂ of a second class C₂ of signal shapes, signal shapes S₃ of a third class C₃ of signal shapes, signal shapes S₄ of a fourth class C₄ of signal shapes, signal shapes S₅ of a fifth class C₅ of signal shapes, or undefined (e.g., unknown or non-classified) signal shapes Sₓ. It is understood that the signal shape may be defined by a varying signal strength as a function of time. With reference to FIG. 3A to FIG. 3C, the signal S is a voltage signal and the signal shapes are depicted as typical voltage signals shapes of neuro-signals and the processing element 110e is a memristor element that causes a characteristic electric current signal I as a response to the input voltage signals. However, any other signal can be classified or identified in a similar way.

According to various aspects, a suitable processing element 110e (e.g., in this example a memristor element) may be utilized to provide a suitable measurable physical quantity (e.g., in this case an electric current, I, in the case that the signal is a voltage signal) that is a function of both the signal S and a respective additional signal (denoted as reference signals R(R₁, R₂, R₃, R₄, R₅)) associated with a respective one of the classes C(C₁, C₂, C₃, C₄, C₅). The additional signal may be a first electric reference signal R₁ (e.g., a voltage reference signal in the case that the signal is a voltage signal) that is associated with, for example, the first class C₁ for classifying the electric input signal S into the first class C₁; the additional signal may be a second electric reference signal R₂ (e.g., a voltage reference signal in the case that the signal is a voltage signal) that is associated with, for example, the second class C₂ for classifying the electric input signal S into the second class C₂; the additional signal may be a third electric reference signal R₃ (e.g., a voltage reference signal in the case that the signal is a voltage signal) that is associated with, for example, the third class C₃ for classifying the electric input signal S into the third class C₃; the additional signal may be a fourth electric reference signal R₄ (e.g., a voltage reference signal in the case that the signal is a voltage signal) that is associated with, for example, the fourth class C₄ for classifying the electric input signal S into the fourth class C₄; the additional signal may be a fifth electric reference signal R₅ (e.g., a voltage reference signal in the case that the signal is a voltage signal) that is associated with, for example, the fifth class C₅ for classifying the electric input signal S into the fifth class C₅. Since the respective reference signal R is associated with the corresponding class C for classifying the electric input signal S, an electric current signal I(I₁, I₂, I₃, I₄, I₅, Iₓ) provided by a memristive element 110e (or any other suitable processing element 110e) may be characteristic for a case in which the electric input signal S corresponds to the respective class C₁, C₂, C₃, C₄, C₅. However, the electric current I provided by the memristive element 110e may not be characteristic for a case in which the electric input signal S does not corresponds to the respective class C₁, C₂, C₃, C₄, C₅ or, in some aspects, the electric current signal Iₓ provided by the memristive structure 110 may be characteristic for another class C_{X(X≠1, 2, 3, 4, 5)} for a case in which the electric input signal S does not corresponds to any of the classes C₁, C₂, C₃, C₄, C₅.

According to various aspects, an electric analysis circuit 120 may be used to determine one or more characteristics of the electric current signal I(I₁, I₂, I₃, I₄, I₅, Iₓ) to determine the class C associated with the electric input signal S based on the one or more characteristics of the electric current signal I. The electric analysis circuit 120 may include a current integrator 120e to at least timewise integrate the electric current signal I(I₁, I₂, I₃, I₄, I₅, Iₓ) to determine the class C associated with the electric input signal S based on the one or more characteristics of a current integration value FI(FI₁, FI₂, FI₃, FI₄, FI₅, FIₓ) of the electric current signal I(I₁, I₂, I₃, I₄, I₅, Iₓ). The current integration value FI(FI₁, FI₂, FI₃, FI₄, FI₅, FIₓ) may be a feature value for the electric current signal I(I₁, I₂, I₃, I₄, I₅, Iₓ) used as a feature F to analyze the signal S in accordance with the classes C introduced by the reference voltage signals R.

As illustrated in FIG. 3B, the electric analysis circuit 120 may include one or more current integrators 120e-a, 120e-b to at integrate the electric current signal I(I₁, I₂, I₃, I₄, I₅, Iₓ) for a first time interval to determine the class C associated with the electric input signal S based on the one or more characteristics of a first current integration value FIa(FIa₁, FIa₂, FIa₃, FIa₄, FIa₅, FIaₓ) of the electric current signal I(I₁, I₂, I₃, I₄, I₅, Iₓ) and for a second time interval to determine the class C associated with the electric input signal S based on the one or more characteristics of a second current integration value FIb(FIb₁, FIb₂, FIb₃, FIb₄, FIb₅, FIbₓ) of the electric current signal I(I₁, I₂, I₃, I₄, I₅, Iₓ). The current integration values FIa, FIb may be feature values for the electric current signal I(I₁, I₂, I₃, I₄, I₅, Iₓ) used as features F to analyze the signal S in accordance with the classes C introduced by the reference voltage signals R.

FIG. 3C shows an example, wherein an input signal S, e.g., an electric voltage signal, is (e.g., simultaneously) supplied to a respective first electrode (e.g., top electrode TE) of a plurality of (in this exemplary case five) memristor elements (210m) as the processing elements 110e. In this exemplary case, the input signal S is a signal of the third class S₃. Each of the memristor elements is supplied with a corresponding one of a plurality of (in this case five) reference signals R₁, R₂, R₃, R₄, R₅ associated with a plurality of (in this case five) classes C₁, C₂, C₃, C₄, C₅ to identify whether or not the input signal S is associated with one of the plurality of classes C₁, C₂, C₃, C₄, C₅ and/or to classify input signals in accordance with the plurality of classes C₁, C₂, C₃, C₄, C₅. The reference signals are supplied to a respective second electrode (e.g., bottom electrode BE) of the plurality of memristor elements (210m). In some aspects, the first electrode to which the input signal S is supplied to can be a shared electrode of the plurality of memristor elements (210m). The plurality of memristor elements (210m) may be, for example, analog switchable barrier memristors as know, for example, for BiFeO based memristors. A barrier switching memristor combines a low resistivity with a beneficial non-linear current/voltage behavior. A barrier switching memristor has a non-linear current/voltage behavior over a voltage range of at least 5 V and a current range over more than two orders of magnitude (e.g., the electric current can vary by a factor of 100 or more in a voltage range of 0 V to 10 V).

Each of the memristor elements (210m) causes a response in terms of a electric current signal I(I₁, I₂, I₃, I₄, I₅) as a function of the voltage difference between the respective two electrodes of the memristor elements (210m), wherein the voltage difference is defined by the time dependent difference between input signal and the respective reference signal R₁, R₂, R₃, R₄, R₅. The current integration value FI(FI₁, FI₂, FI₃, FI₄, FI₅) may be related directly with the time dependent difference between input signal and the respective reference signal R₁, R₂, R₃, R₄, R₅ and allows to identify and/or classify the input signal based thereon. In this exemplary case, the third current integration value F₃ is significant (e.g., the least absolute value) and therefore the input signal S(S₃) can be identified and/or classified to be a signal of the third class C₃. The current integration values FI(FI₁, FI₂, FI₃, FI₄, FI₅) of the plurality of memristor elements (210m) allows for a classification of the input signals S and/or for a recognition of the presence of an input signal having a specific characteristic (e.g., in this case signal shape).

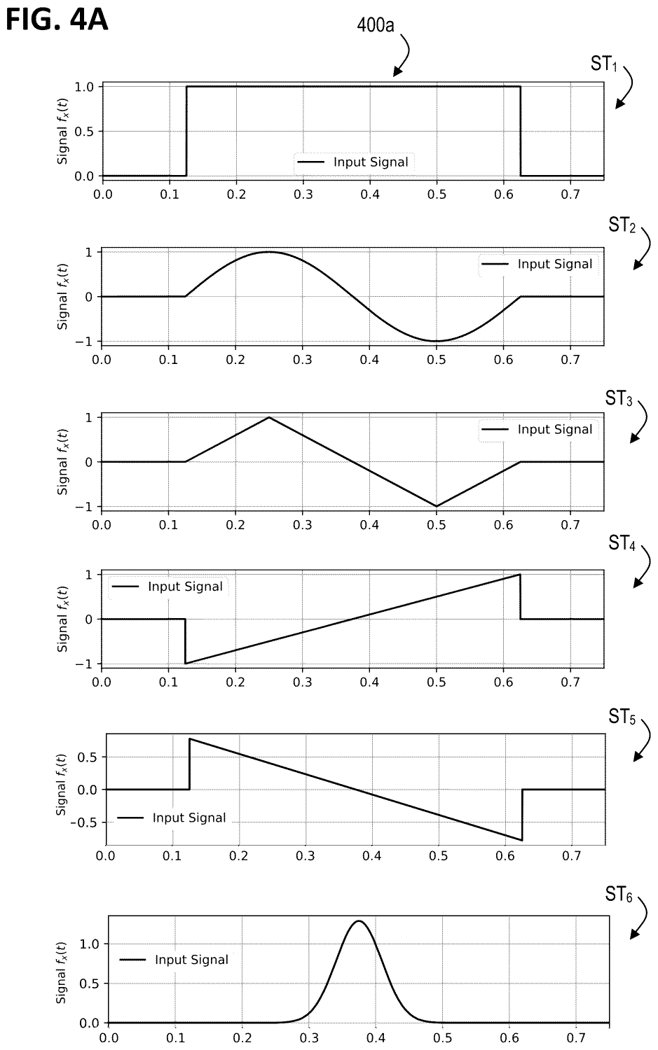

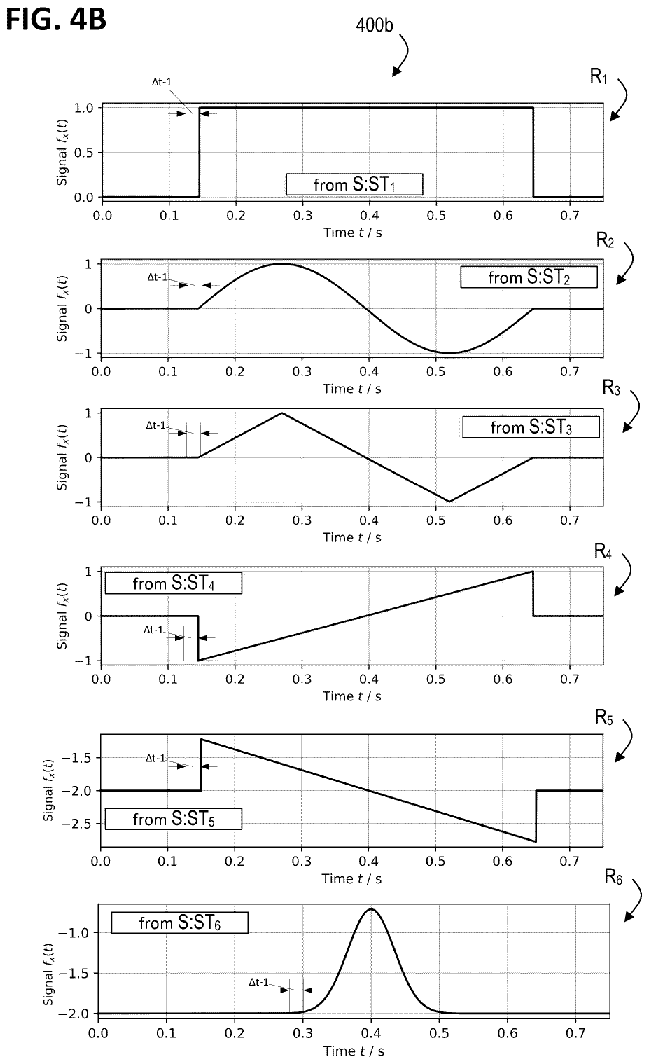

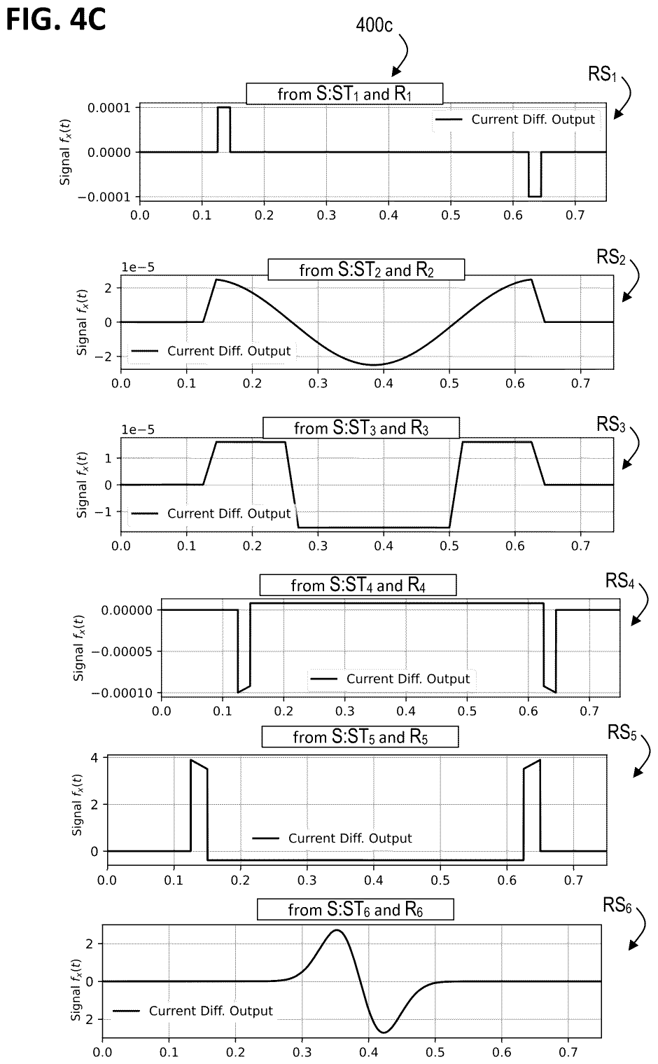

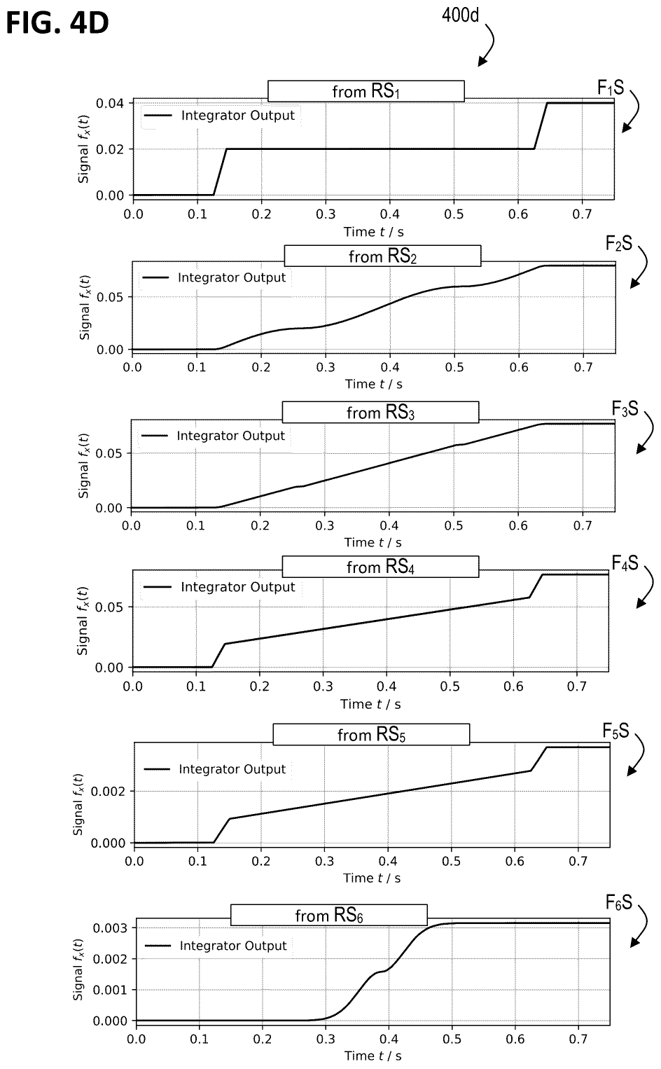

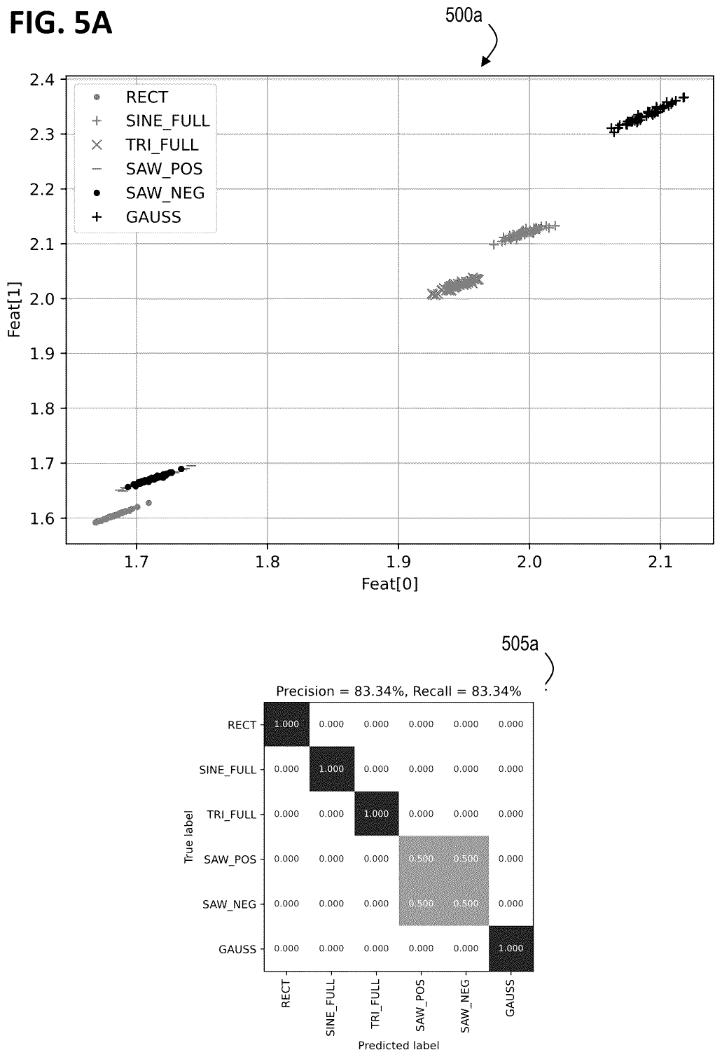

The feature extraction circuit 100 (and a recognition device 300 including the feature extraction circuit 100) may include one or more processors 170 configured to determine a class C(C₁, C₂, C₃, C₄, C₅, Cₓ) associated with the input signals S(S₁, S₂, S₃, S₄, S₅, Sₓ) based on the one or more feature signals FS, e.g., as exemplarily illustrated in FIGS. 3A to 3C based on electric current signals I(I₁, I₂, I₃, I₄, I₅, Iₓ). The class C(C₁, C₂, C₃, C₄, C₅, Cₓ) associated with the input signals S(S₁, S₂, S₃, S₄, S₅, Sₓ) may be associated with a class-specific signal type (see FIG. 4A to FIG. 4D). The one or more processors 170 may be configured to determine the respective class C(C₁, C₂, C₃, C₄, C₅, Cₓ) associated with the input signal S(S₁, S₂, S₃, S₄, S₅, Sₓ) of a specific type based on analyzing one or more feature values. As exemplarily illustrated in FIGS. 3A to 3C, current values or charge values (integrated current values) FI(FI₁, FI₂, FI₃, FI₄, FI₅, FIₓ) may be extracted as the one or more feature values of the one or more feature signals I(I₁, I₂, I₃, I₄, I₅, Iₓ). However, any other feature values may be extracted in a similar way depending on the desired type of response signals and the desired principle of analyzing the response signals by the analysis circuit 120.

In some aspects, the one or more processors 170 may be configured to determine the respective class C(C₁, C₂, C₃, C₄, C₅, Cₓ) associated with the input signal S(S₁, S₂, S₃, S₄, S₅, Sₓ) based on clustering the one or more feature values of the one or more feature signals in an n-dimensional feature space (see, for example, FIGS. 5A to 5D and 6A to 6D). The number n of dimensions of the n-dimensional feature space is associated with the number of the one or more reference signals having distinct modifications. In other words, the more distinct reference signals R the more distinct features may be extracted from the input signals. The number n of dimensions of the n-dimensional feature space may be different from a number N of classes of the classes (C, C₁, . . . , C_{N}) to be classified (only as an example, FIGS. 5A to 5D and 6A to 6D shows clustering of 6 classes with two or three feature sets derived by use of three distinctly modified branches reference signals per signal event overlayed with the input signals).

FIG. 3C shows various aspects of a classification device 300 for classifying an electric input signal S. In this exemplary case, the electric input signal S is of a third type S₃ of five different types. In other words, the electric input signal S is of a third class C₃ of five classes C(C₁, C₂, C₃, C₄, C₅) used for the classification. A class Cₓ may be used to classify the electric input signal S as not classifiable into the remaining classes C(C₁, C₂, C₃, C₄, C₅). The electric input signal S may be (e.g., sequences of) neuro-signals. In this exemplary case, the electric input signal S may be a neuro-signal of the third class C₃, as illustrated in FIG. 3C in the diagrams for the electric input signal S applied as U_top (sample).

According to various aspects, the classification device 300 may include an input node to receive the electric input signal (S) and a set of memristive structures 110e, 210m. Each of the set of memristive structures 110e, 210m includes a first electrode TE. The first electrodes TE may be coupled to the input node or may be part of the input node. The first electrodes TE may be provided as a common electrode for the set of memristive structures 110e, 210m.

According to various aspects, the classification device 300 may include a reference circuit 130 configured to generate an electric reference signal R, e.g., one reference signal for each of the set of memristive structures 110e, 210m. The reference circuit 130 may be configured to generate one specific reference signal R(R₁, R₂, R₃, R₄, R₅) for a corresponding memristive structure of the set of memristive structures 110e, 210m. Each of the memristive structures 110e, 210m may be configured to cause an electric response signal (e.g., the electric current response signals I(I₁, I₂, I₃, I₄, I₅) as a function of both the electric input signal S received at the input node and the electric reference signal R generated by the reference circuit 130.

According to various aspects, the classification device 300 may include an electric analysis circuit 120 coupled to the set of memristive structures 110e, 210m to determine one or more characteristics FI of the electric response signal I caused by the corresponding memristive structure 110e, 210m. The determined one or more characteristics FI(FI₁, FI₂, FI₃, FI₄, FI₅) may be current integration values of the electric response signals I(I₁, I₂, I₃, I₄, I₅). The memristive structure 110e-3 that receives the reference signal R₃ that corresponds to the class C₃ of the electric input signal S₃ causes an electric response signal 13 that has a current integration value FI₃ close to zero since the difference to the class specific reference signal R₃ is a least difference. The class specific reference signal may be determined as a mean signal of a corresponding class, as illustrated in the diagrams of the reference signals applied as U_bot (Ref.). The memristive structures 110e-1, 110e-2, 110e-4, 110e-5 receiving other reference signals R(R₁, R₂, R₄, R₅) corresponding to other classes C(C₁, C₂, C₄, C₅) not corresponding to the electric input signal S₃ cause electric response signals I(I₁, I₂, I₄, I₅) having current integration values FI(FI₁, FI₂, FI₄, FI₅) not close to zero. It is now clear from the configuration of the classification device 300, that in the case that the electric input signal S₁ corresponds to the first class C₁, the memristive structures 110e-1 that receives the reference signal R₁ that corresponds to the first class C₁ causes the electric response signal I₁ having a least current integration value FI₁ compared to the integration values of the other memristive structures; and that in the case that the electric input signal S₂ corresponds to the second class C₂, the memristive structures 110e-2 that receives the reference signal R₂ that corresponds to the second class C₂ causes the electric response signal I₂ having a least current integration value FI₂ compared to the integration values of the other memristive structures; and so forth.

According to various aspects, the classification device 300 may include one or more processors 170 configured to determine a class C associated with the electric input signal S based on the one or more characteristics of the electric response signal RS determined by the electric analysis circuit 120 as described herein.

According to various aspects, the classification device 300 may include a sensor signal input node to receive a sensor signal, and a mapping circuit 140 to modify the sensor signal to provide the electric input signal, wherein the electric input signal is in a predefined signal range (current and/or voltage range), as described herein.

According to various aspects, the one or more characteristics of the electric response signal may include a time integrated signal (a time integrated current signal FI) of the electric response signal.

According to various aspects, each of the memristive structures 110e, 210m may include a first terminal (e.g., a top electrode) and a second terminal (e.g., a bottom electrode), and the classification device 300 may be configured to provide a first voltage at the first terminal as a function of the electric input signal S and to provide a second voltage at the second terminal as a function of the electric reference signal R. The classification device 300 may be configured such that an electric current I flows through the memristive structure. The electric current I is generated by a time varying voltage difference between the first voltage provided at the first terminal and the second voltage provided at the second terminal.

However, the electric input signal S may be combined with the electric reference signal R before the combined signal is feed to the respective memristive structure. In this case, the memristive structure may include a first terminal and a second terminal, and the classification device 300 may be configured to provide a first time varying voltage at the first terminal as a function of both the electric input signal S and the reference signal R. The classification device 300 may be configured to provide a second voltage at the second terminal to bring the memristive structure into a predefined operation voltage range. The second voltage may be a positive voltage to shift into a positive operation voltage range of the memristive structure, or a negative voltage to shift into a negative operation voltage range of the memristive structure, or ground voltage. The classification device 300 may be configured such that a time varying electric current I flows through the memristive structure generated by the first time varying voltage provided at the first terminal.

FIG. 3C illustrates the operation of the classification device 300 based on memristive structures 110e, 210m that are voltage controlled, i.e., the input and reference signals are provided as voltage signals. However, in a similar way, the operation of the classification device 300 based on memristive structures 110e, 210m may be current controlled, i.e., the input and reference signals are provided as electric current signals, wherein the response signal is a voltage signal, as described herein.

According to various aspects, the classification device 300 may include a delay circuit configured to synchronize the electric input signal and the electric reference signal with one another by delaying the electric input signal and/or the electric reference signal, as described herein. According to various aspects, the classification device 300 may include an event detector circuit configured to detect reception of the electric input signal at the input node and to modify and/or trigger the electric reference signal generated by the reference circuit based on the detected reception of the electric input signal, as described herein. According to various aspects, the reference circuit 130 may be configured to generate the electric reference signals R by branching and modifying the electric input signal S, as described herein.

According to various aspects, the one or more characteristics of the electric response signal (RS) may include one or more characteristic values that are in a predefined range in the case that the electric input signal S belongs to a corresponding class C and that are outside the predefined range in the case that the electric input signal does not belong to the corresponding class C. As an example, the integrated current values FI may be near zero (e.g., 0.2, e.g., in a range from about −10 to about 10) in the case that the electric input signal S₃ belongs to a corresponding class C₃ and the integrated current values FI may be farther away from zero (e.g., −70.3; −111.1; 72.8; −119.5; e.g., greater than 10 or less than −10) in the case that the electric input signal S does not belong to the corresponding class C.

According to various aspects, the one or more characteristic values are less than one or more corresponding threshold values in the case that the electric input signal belongs to the corresponding class and the one or more characteristic values are greater than the one or more corresponding threshold values in the case that the electric input signal does not belong to the corresponding class.

According to various aspects, the one or more characteristic values are one or more voltage values representing an integral of the electric current during a predefined time interval and the one or more corresponding threshold values are one or more corresponding threshold voltage values; and/or the one or more characteristic values are one or more charge values representing an integral of the electric current during a predefined time interval and the one or more corresponding threshold values are one or more corresponding threshold charge values; and/or the one or more characteristic values are one or more average current values representing an average of the electric current during a predefined time interval and the one or more corresponding threshold values are one or more corresponding threshold average current values.

According to various aspects, the electric input signal S may be a time dependent voltage signal and the electric reference signal may be a time dependent reference voltage signal. According to various aspects, the electric input signal S may be a time dependent current signal and the electric reference signal may be a time dependent reference current signal.

According to various aspects, the memristive structure 110e, 210m has a non-linear current/voltage characteristic, preferably, the memristive structure has a transcendent current/voltage characteristic.

According to various aspects, a waveform of the electric reference signal S represents an electro-neuro-signal associated with a class of electro-neuro-signals as illustrated in FIGS. 3A to 3C or, in a similar way, an electro-cardio-signal associated with a class of electro-cardio-signals. In particular, any complex time dependent signal can be analyzed (e.g., classified) with the classification device 300 as described herein.

According to various aspects, the one or more processors 170 may be configured to determine the class C associated with the electric input signal S based on a clustering operation with the one or more characteristics of the of the electric response signal (RS) caused by the memristive structure as input for the clustering operation, as illustrated exemplarily in FIGS. 5A to 5D and FIGS. 6A to 6D.

According to various aspects, the features extracted from various input signals may be plotted (e.g., clustered) in an n-dimensional feature space to allow for a distinction between the respective input signals, as exemplarily shown in more detail below.

FIG. 4A illustrates a set of diagrams 400a showing different signal types ST (also referred to as signal shapes) that may be present as input signal S to be identified or classified. The signal shapes ST are exemplarily depicted and processed as electric voltage signals and/or current signals, however, the principles described herein can be applied to an suitable signal that can be processed in the same or in a similar way. The input signal S may be a function of time fx(t) that may define the respective signal type ST of the input signal S. The signal shapes ST may include a signal type ST₁ including a substantially rectangular shaped pulse, a s signal type ST₂ including a substantially sine shaped pulse, a signal type ST₃ including a substantially triangular shaped pulse, a signal type ST₄ including a substantially linear shaped pulse, a signal type ST₅ including a substantially inverse linear shaped pulse, and/or a signal type ST₆ including a substantially gaussian shaped pulse.

FIG. 4B illustrates a set of diagrams 400b showing reference signals R₁, R₂, R₃, R₄, R₅, R₆ to be combined with the input signal S to cause a corresponding response signals RS₁, RS₂, RS₃, RS₄, RS₅, RS₆ (shown in FIG. 4C) for the input signal S with the respective input signal types ST₁, ST₂, ST₃, ST₄, ST₅, ST₆. The reference signal R and the response signal RS may be a function of time fx(t) that may define the respective signal shapes thereof.

As described herein, the reference signals R₁, R₂, R₃, R₄, R₅, R₆ may be branched with a time delay Δt−1 from the input signal S, and therefore the reference signals R₁, R₂, R₃, R₄, R₅, R₆ may be associated with the signal type ST of the input signal S. Illustratively, if the input signals are of a different type, the distinct reference signals may be cause (e.g., by the or more signal modifier elements of a reference circuit 130). In this simple exemplary case, the reference circuit 130 causes a delay such the input signal S and the refence signal R have the same signal type ST but a time delay between one another. In addition, an offset may be created (e.g., added to the input signal and/or to the reference signal) to cause the response signal RS within a predefined processing voltage range for the processing elements 110e of the processing circuit 110. During the analyses, the offset may be compensated to avoid a direct influence of the offset for the analysis of the response signal RS (e.g., via current integrators of the electric analysis circuit 120).

FIG. 4C illustrates a set of diagrams 400c showing response signals RS₁, RS₂, RS₃, RS₄, RS₅, RS₆ that are a superposition (e.g., via a resistor, diode, and/or memristor) of the respective input signal S with the corresponding delayed reference signals R for the various signal types ST₁, ST₂, ST₃, ST₄, ST₅, ST₆ that the input signal S may include. The response signals are shown exemplarily as current difference outputs of the processing circuit 110 that processes the input signal S and the reference signal R as voltage signals and causes a current output that is a function of the voltage difference between the input signal S and the reference signal R. The response signals RS₁, RS₂, RS₃, RS₄, RS₅, RS₆ are caused by super positioning of the input signal with the signal types ST₁, ST₂, ST₃, ST₄, ST₅, ST₆ with the respectively caused reference signal R₁, R₂, R₃, R₄, R₅, R₆ branched from the input signal S and delayed with a predefined delay relative to the input signal S to superposition the corresponding signal shapes of the input signal S and the reference signal R. Response signal RS₁ is caused by a current difference between input signal having the signal type ST₁ and the reference signal R₁ branched from the input signal S; response signal RS₂ is caused by a current difference between input signal having the signal type ST₂ and the reference signal R₂ branched from the input signal S; response signal RS₃ is caused by a current difference between input signal having the signal type ST₃ and the reference signal R₃ branched from the input signal S; response signal RS₄ is caused by a current difference between input signal having the signal type ST₄ and the reference signal R₄ branched from the input signal S; response signal RS₅ is caused by a current difference between input signal having the signal type ST₅ and the reference signal R₅ branched from the input signal S; and response signal RS₆ is caused by a current difference between input signal having the signal type ST₆ and the reference signal R₆ branched from the input signal S. In this configuration, input signals of various types cause, in the feature extraction circuit 100, type specific response signals RS.

According to various aspects, the time dependent current difference output (in other words the illustrated response signals RS) is specific for the signal shape of the input signal and may be used for feature extraction (e.g., for identifying a signal type of the input signal, for classifying the input signal in accordance with various signal shape related classes, only as examples), as explained herein.

FIG. 4D illustrates a set of diagrams 400d showing feature signals F₁S, F₂S, F₃S, F₄S, F₅S, F₆S caused by a current integration of the respective response signals RS₁, RS₂, RS₃, RS₄, RSₛ, RS₆ (in this case, the feature may be a current difference between the input signal S and its corresponding reference signal R and the feature value may be a current integration value as described above with reference to FIGS. 3A to 3C, wherein the reference signal R is branched and modified from the input signal S). The feature signals F₁S, F₂S, F₃S, F₄S, F₅S, F₆S represent therefore a set of time dependent feature values F₁(R₁, S:ST₁), F₂(R₂,S:ST₂), F₃(R₃,S:ST₃), F₄(R₄,S:ST₄), F₅(R₅,S:ST₅), F₆(R₆,S:ST₆) that represent the signal type ST of the input signal S. As an example, the feature value at a certain time (e.g., at the end of the integration) may be used as the feature value FI₁, FI₂, FI₃, FI₄, FI₅, FI₆ to identify and/or classify the input signal S with respect to its signal type ST. Another set of feature value can be obtained by generating another set of reference signals R based on, for example, a second predefined delay (or another offset, or any other modification of the branched reference signal).

According to various aspects, any data representing a specific time development of a feature value or any absolute or relative quantity related to the specific feature values can be used to identify and/or classify the input signal S with respect to its signal type ST.

FIG. 5A, FIG. 5B, FIG. 5C, and FIG. 5D illustrate four evaluation diagrams 500a, 500b, 500c, 500d of the feature values obtained by random input signals having the signal types mentioned in FIGS. 4A to 4D, wherein the horizontal axis of the evaluation diagrams shows a first set of feature values Feat[0] extracted via the principle described herein by use of a first offset U_{off}(1) and a first delay Δt_{dly}(1) to modify the branched reference signals R and wherein the vertical axis of the evaluation diagrams shows a second set of feature values Feat[1] extracted via the principle described herein by use of a second offset U_{off}(2) and a second delay Δt_{dly}(2) to modify the branched reference signals R). The feature values shown in evaluation diagram 500a in FIG. 5A were determined by processing the signals via a resistor as the processing element, the feature values shown in evaluation diagram 500b in FIG. 5B were determined by processing the signals via a diode as the processing element, the feature values shown in evaluation diagram 500c in FIG. 5C were determined by processing the signals via a series connection of a diode and a resistor as the processing elements, and, the feature values shown in evaluation diagram 500d in FIG. 5D were determined by processing the signals via a memristor as the processing element. The corresponding recognition matrices 505a, 505b, 505c, 505d shows a comparison of the predicted (recognized) label (also referred as the determined class) relative to the true label which results in a certain precision for the determination of the label (class). The precision of the principles described herein is, in some aspects, higher, in the case the processing elements with a non-linear current/voltage behavior are used for the processing of the signals. Compared to the resistor (FIG. 5A) and the series connection of diode and resistor (FIG. 5C) with a precision (also referred to as recognition rate) of about 83%, die diode (FIG. 5B) has a precision of about 100% and the memristor (FIG. 5D) has a precision of about 97%.

However, an advantage of using the memristor as processing element may be that the power consumption is several orders of magnitude lower than compared to the diode. See currents in the microamp ranges for the memristor (FIG. 2G) compared to hundreds of milliamp ranges for the diode (see FIG. 2C).

It is noted that the feature values where obtained as integrated absolute current values (see FIG. 4D) and therefore, the features of symmetric positive linear shaped pulse and negative linear shaped pulse input signals have similar features and can not be distinguished from one another. This can be improved, for example, by use of more than one feature value obtained from the integration of the response signal, e.g., by use of a current value at a first time and at a second time later than the first time to include time behavior of the feature values into consideration. Another example would include use of a first integration of positive signal portions and a second integration of negative signal portions to include polarity behavior of the feature values into consideration.

It is noted that the dimension of the feature space (two dimensions shown in FIG. 5A to FIG. 5D) can be selected as deemed appropriate for the analysis of the feature values (the feature space may have more dimensions than the number of signal types for the classification). According to various aspects, the classification of the input signals into a plurality of classes may include a clustering algorithm, e.g., as exemplarily illustrated in FIG. 5A to FIG. 5D.

FIG. 6A, FIG. 6B, FIG. 6C, and FIG. 6D each illustrates a signal analysis based on a feature space with more than two dimensions, i.e., in this case by use of three sets of feature values Feat[0], Feat[1], Feat[2] extracted via the principle described herein, e.g., similar as described with reference to FIGS. 5A to 5D. In some aspects, the dimensionality of the feature space can be increased by adding various sets of reference signals with distinct modifications of the input signal. In other aspects, the dimensionality of the feature space can be increased by adding various sets of feature values obtained from the response signal in distinct manner (e.g., at different times, e.g., relative values, e.g., polarity distinct values, only as examples. The precision of the determination of the correct type of input signals via the principle described herein may be very precise even though only three sets of feature values Feat[0], Feat[1], Feat[2] are used for the classification (see corresponding recognition matrices 505a, 505b, 505c, 505d). FIG. 6A shows a feature extraction based on a resistor as processing element having a precision of determination of the correct type of input signals of about 83%. FIG. 6B shows a feature extraction based on a diode as processing element having a precision of determination of the correct type of input signals of about 100%. FIG. 6C shows a feature extraction based on a series connection of a resistor and a diode as processing elements having a precision of determination of the correct type of input signals of about 97%. FIG. 6D shows a feature extraction based on a memristor as processing element having a precision of determination of the correct type of input signals of about 100%. It can be seen, that in this exemplary cases a signal processing by use of electric non-linear processing elements (such as diodes, resistive diodes, memristors, as examples) leads to higher recognition rates.

As illustrated with reference to the clustering shown in FIGS. 5A to 6D, a range for the feature values can be determined in which no classification is possible. Such one or more ranges can be used to monitor the input signal S for abnormal/fault conditions. In the case that a fault event is detected, an error message can be issued and send or any other action (e.g., a recalibration) can be triggered based thereon.

In the following, various examples are provided that may include one or more aspects described above with reference to one of the devices and/or methods. It may be intended that aspects described in relation a device may apply also to one or more of the methods, and vice versa. Further, it may be intended that aspects described in relation to the recognition device may apply also to one or more of the other devices described herein. Similarly, aspects described in relation to one of the methods may apply also to one or more other ones of the methods.

Example 1 is feature extraction circuit (or a recognition device or a classification device) including: an input node (110s) to receive an input signal (S); a reference circuit (130) configured to generate one or more reference signals (R, R₁, . . . , R_{N}) by branching the input signal (S) and by modifying the branched input signal (S) via one or more signal modifier elements (130e); a processing circuit (110) configured to cause one or more response signals (RS, RS₁, . . . , RS_{N}), each of the one or more response signals (RS, RS₁, . . . , RS_{N}) is a function of both the input signal (S) received at the input node (110s) and one of the one or more reference signals (R, R₁, . . . , R_{N}) generated by the reference circuit (130), the one or more response signals (RS, RS₁, . . . , RS_{N}) are associated with one or more features (F, F₁, . . . , F_{N}) of the input signal (S); an analysis circuit (120) coupled to the processing circuit (110) for analyzing the one or more response signals (RS, RS₁, . . . , RS_{N}) to generate one or more feature signals (FS, F₁S, . . . , F_{N}S) representing one or more feature values (FI, Feat) associated with one or more features (F, F₁, . . . , F_{N}) of the input signal; and an output node (120o) to output the one or more feature signals (FS, F₁S, . . . , F_{N}S).

In Example 2, the feature extraction circuit (100) of Example 1 may optionally further include: a sensor signal input node (140s) to receive a sensor signal (SENSE), and a mapping circuit (140) to modify (e.g., level shift, e.g., amplify, as examples) the sensor signal to provide the input signal (S), wherein the input signal (S) is in a predefined signal range for processing the input signal (S) via the processing circuit (110).

In Example 3, the feature extraction circuit (100) of Example 2 may optionally further include that the sensor signal (SENSE) is an analog or digital sensor signal and that the input signal (s) is an analog input signal.

In Example 4, the feature extraction circuit (100) of any one of Examples 1 to 3 may optionally further include that the analysis circuit (120) includes one or more time integration circuits and that the one or more feature signals (FS, F₁S, . . . , F_{N}S) are one or more time integration signals of the corresponding one or more response signals (RS, RS₁, . . . , RS_{N}).

In Example 5, the feature extraction circuit (100) of any one of Examples 1 to 4 may optionally further include that the one or more feature values (FI, Feat) include integration values of one or more corresponding time integration signals determined from the corresponding one or more response signals (RS, RS₁, . . . , RS_{N}) at a predefined integration time.

In Example 6, the feature extraction circuit (100) of any one of Examples 1 to 5 may optionally further include that the one or more feature values (FI, Feat) include a first set of integration values of one or more corresponding time integration signals at a predefined first integration time and that the one or more feature values include a second set of integration values of one or more corresponding time integration signals at a predefined second integration time different from the first integration time.

In Example 7, the feature extraction circuit (100) of any one of Examples 1 to 6 may optionally further include that the one or more feature values (FI, Feat) include one or more relative values and/or one or more dynamic values representing a change of the response signal in a predefined time.

In Example 8 the feature extraction circuit (100) of Example 7 may optionally further include that the one or more relative values and/or the one or more dynamic values include a set of time integration values determined based on a change of the time integration signals during a predefined integration time or based on a ratio between time integration values at different times during a predefined integration time.

In Example 9, the feature extraction circuit (100) of any one of Examples 1 to 8 may optionally further include that the analysis circuit (120) is configured to generate the one or more feature signals (FS, F₁S, . . . , F_{N}S) to include a first set of feature values associated with positive signal portions of the input signal and a second set of feature values associated with negative signal portions of the input signal.

In Example 10, the feature extraction circuit (100) of any one of Examples 1 to 9 may optionally further include that the one or more signal modifier elements (130e) include one or more of the following group of signal modifier elements: one or more time delay elements to provide one or more predefined signal time delays; and/or one or more offset elements to provide one or more predefined signal offsets; and/or one or more amplifier elements to provide one or more predefined signal amplifications; and/or one or more non-linear amplifier elements to provide one or more predefined non-linear signal amplifications; and/or one or more distortion elements to provide one or more predefined signal distortions; and/or one or more signal shape modifier elements to provide one or more predefined signal shape modifications; and/or one or more inverter elements to provide a predefined inverted signal; and/or one or more clipping elements to provided a predefined clipped signal.

In Example 11, the feature extraction circuit (100) of any one of Examples 1 to 10 may optionally further include that the processing circuit (110) includes one or more processing elements (110e), each of the one or more processing elements (110e) includes a first terminal and a second terminal, and that the processing circuit (110) is configured to provide a first voltage at the first terminal as a function of the input signal (S) and to provide a second voltage at the second terminal as a function of a corresponding reference signal (R) generated by the reference circuit (130).

In Example 12, the feature extraction circuit (100) of any one of Examples 1 to 10 may optionally further include that the processing circuit (110) includes one or more processing elements (110e), each of the one or more processing elements (110e) includes a first terminal and a second terminal; and that the processing circuit (110) is configured to provide a first voltage at the first terminal as a function of both the input signal (S) and the reference signal (R) generated by the reference circuit (130) and to provide a second voltage at the second terminal to provide a ground terminal and/or to bring the processing elements (110e) into a predefined operation voltage range.

In Example 13, the feature extraction circuit (100) of any one of Examples 1 to 12 may optionally further include that the processing circuit (110) includes one or more processing elements (110e), each of the one or more processing elements (110e) includes a first terminal and a second terminal; and that the processing circuit (110) is configured such that an electric current that flows through the respective processing element (110e) of the one or more processing elements (110e), the electric current being generated by a time dependent voltage difference between the first voltage provided at the first terminal and the second voltage provided at the second terminal.

In Example 14, the feature extraction circuit (100) of any one of Examples 1 to 13 may optionally further include that one or more processing elements (110e) of the processing circuit (110) includes one or more of the following types of processing elements: one or more resistors; and/or one or more diodes; and/or one or more memristors; and/or one or more capacitors; and/or one or more inductors.

In Example 15, the feature extraction circuit (100) of any one of Examples 1 to 14 may optionally further include that the processing circuit (110) includes one or more processing elements (110e) configured to provide a non-linear current/voltage characteristics to generate the one or more response signals (RS, RS₁, . . . , RS_{N}) from the input signal (S) and the corresponding one or more reference signals (R, R₁, . . . , R_{N}) with the non-linear current/voltage characteristics.

In Example 16, the feature extraction circuit (100) of any one of Examples 1 to 15 may optionally further include that the analysis circuit (120) includes one or more analyzing elements configured to provide a non-linear current/voltage characteristics to generate the one or more feature signals (FS, F₁S, . . . , F_{N}S) from the corresponding one or more response signals (RS, RS₁, . . . , RS_{N}) with the non-linear current/voltage characteristics.

In Example 17, the feature extraction circuit (100) of any one of Examples 1 to 16 may optionally further include: an input delay circuit (150) configured to delay the input signal received at the input node (110s) or to delay the input signal provided to the input node (110s).

In Example 18, the feature extraction circuit (100) of any one of Examples 1 to 17 may optionally further include that the reference circuit (130) and the processing circuit (110) are configured to synchronize the input signal and the reference signal with one another by delaying the input signal and/or the reference signal.

In Example 19, the feature extraction circuit (100) of any one of Examples 1 to 18 may optionally further include that the reference circuit (130) and the processing circuit (110) are configured to overlay the input signal with a corresponding one of the one or more reference signals (R, R₁, . . . , R_{N}) and to provide a respective overlay signal to a corresponding one of one or more processing elements.

In Example 20, the feature extraction circuit (100) of any one of Examples 1 to 19 may optionally further include: an event detector circuit (160) configured to detect reception of the input signal at the input node (110s) and to control an operation of the processing circuit (110), the analysis circuit (120), and/or the reference circuit (130) based on a detected reception.

In Example 21 the feature extraction circuit (100) of Example 20 may optionally further include that the control of an operation includes: activating the processing circuit (110); and/or delaying the input signal (s); and/or activating the analysis circuit (120); and/or resetting one or more signal integrators; and/or activating the reference circuit (130); and/or modifying and/or triggering the reference signal (R) generated by the reference circuit (130).

In Example 22, the feature extraction circuit (100) of any one of Examples 1 to 21 may optionally further include that the reference signal (R, R₁, . . . , R_{N}) is a class-specific reference signal of a corresponding class (C, C₁, . . . , Cₓ) such that, in the case that the input signal (S, S₁, . . . , Sₓ) belongs to the corresponding class (C, C₁, . . . , Cₓ), the response signal (RS) and/or the feature signal (FS) are characteristic for the corresponding class (C, C₁, . . . , Cₓ).

In Example 23 the feature extraction circuit (100) of Example 22 may optionally further include that the feature values are within one or more predefined ranges in the case that the input signal (S) is of an input signal type (ST) that belongs to a corresponding class (C); and/or that the feature values are outside the one or more predefined ranges in the case that the input signal (S) is of an input signal type (ST) that does not belongs to a corresponding class (C).

In Example 24 the feature extraction circuit (100) of Example 23 may optionally further include that feature values that are not within any of the one or more predefined ranges are monitored in terms of signal fault detection.

In Example 25, the feature extraction circuit (100) of any one of Examples 1 to 24 may optionally further include that the input signal (s) received at the input node (110s) is a time dependent voltage signal and wherein the one or more reference signals (R, R₁, . . . , R_{N}) are time dependent reference voltage signals; or that the input signal (s) received at the input node (110s) is a time dependent current signal and wherein the one or more reference signals (R, R₁, . . . , R_{N}) are time dependent reference current signals.

In Example 26, the feature extraction circuit (100) of any one of Examples 1 to 25 may optionally further include that a waveform of the one or more reference signals (R) represents one or more types of neuro-signals associated with one or more classes of neuro-signals or represents one or more types of electro-cardio-signals associated with one or more classes of electro-cardio-signals.

In Example 27, the feature extraction circuit (100) of any one of Examples 1 to 26 may optionally further include: one or more processors (170) configured to determine a class (C, C₁, . . . , C_{N}) associated with the input signal based on the one or more feature signals (FS, F₁S, . . . , F_{N}S).

In Example 28 the feature extraction circuit (100) of Example 27 may optionally further include that the class (C, C₁, . . . , C_{N}) associated with the input signal is associated with a class-specific signal type (ST₁, . . . , ST_{N}) of the input signal.

In Example 29 the feature extraction circuit (100) of Example 27 or 28 may optionally further include that the one or more processors (170) are configured to determine the respective class (C, C₁, . . . , C_{N}) associated with the input signal based on analyzing the one or more feature values of the one or more feature signals (FS, F₁S, . . . , F_{N}S).

In Example 30 the feature extraction circuit (100) of Example 29 may optionally further include that the one or more processors (170) are configured to determine the respective class (C, C₁, . . . , C_{N}) associated with the input signal based on clustering the one or more feature values of the one or more feature signals (FS, F₁S, . . . , F_{N}S) in an n-dimensional feature space.

In Example 31 the feature extraction circuit (100) of Example 30 may optionally further include that a number n of dimensions of the n-dimensional feature space is associated with the number of the one or more reference signals having distinct modifications.

In Example 32 the feature extraction circuit (100) of Example 30 or 31 may optionally further include that a number n of dimensions of the n-dimensional feature space is different from a number N of classes of the classes (C, C₁, . . . , C_{N}) to be classified.

In Example 33, the feature extraction circuit (100) of any one of Examples 1 to 32 may optionally further include that the one or more signal modifier elements are one or more configurable signal modifier elements. An example for a configurable signal modifier element is a memristor that can be configured in terms of a memristive state written into the memristor.

In Example 34 the feature extraction circuit (100) of Example 33 may optionally further include that the one or more configurable signal modifier elements are configured based on configuration data obtained from configuration measurements such that the one or more electric response signals associated with one or more class-specific features are distinct from one another.

In Example 35 the feature extraction circuit (100) of Example 33 may optionally further include that the one or more configurable signal modifier elements are configured based on configuration data obtained from configuration measurements such that a recognition rate of a recognition algorithm based on the one or more features is in a predefined range (e.g., 51-100%, e.g., 61-100%, e.g., 71-100%, e.g., 81-100%, e.g., 91-100%).

In Example 36, the feature extraction circuit (100) of any one of Examples 1 to 35 may optionally further include that the analysis circuit and/or the one or more processors are configured to check whether the one or more feature values are within one or more class specific feature value ranges.

In Example 37 the feature extraction circuit (100) of Example 36 may optionally further include that the feature extraction circuit (100) is configured to discard one or more feature signals (FS, F1S, . . . , FNS) in the case the one or more feature values are not within the one or more class specific feature value ranges; and/or that the feature extraction circuit (100) is configured to cause to send an error message in the case the one or more feature values are not within one or more sets (class specific sets) of corresponding one or more feature signal value ranges.

Example 38 is a recognition device configured to detect presence of an input signal of a predefined input signal type, the recognition device including: a feature extraction circuit (100) of any one of claims 1 to 37; and one or more processors configured to detect presence of an input signal of a predefined input signal type based on the based on the one or more feature values represented by the one or more feature signals.

Example 39 is a recognition device configured to detect presence of an object represented by at least one input signal of a predefined input signal type, the recognition device including: a feature extraction circuit (100) of any one of claims 1 to 37; and one or more processors configured to detect presence of the object based on the based on the one or more feature values represented by the one or more feature signals.

Example 40 is a recognition device including, a feature extraction circuit (100) of any one of claims 1 to 37.

The one or more processors referred to herein may include and suitable type of processing entity or combination of processing entities, such as digital and/or analog processors, (e.g., FPGA, CPU, microcontroller, or any other suitable one or more entities to provide the desired functions). The term includes memory integrated within the one or more processors or in communication with the one or more processors for the implementation of the desired one or more operations carried out by the one or more processors.

The terms processing circuit, reference circuit, analysis circuit and the like include any one or more circuit elements and/or one or more processors configured to provide an implementation of the desired one or more functions thereof. Such circuits may be implemented within a microcontroller or within one or more processors. Such circuits may be implemented within a PCB design including any suitable circuit elements such as one or more operational amplifiers, one or more delay elements, one or more inverter elements, one or more comparators, one or more level shifter, only as examples.

Example 41 is a recognition device including: an input node (110s) to receive an input signal (S); a reference circuit (130) configured to generate one or more reference signals (R, R₁, . . . , R_{N}) by branching the input signal (S) and by modifying the branched input signal (S) via one or more signal modifier elements (130e); a processing circuit (110) configured to cause one or more response signals (RS, RS₁, . . . , RS_{N}), each of the one or more response signals (RS, RS₁, . . . , RS_{N}) is a function of both the input signal (S) received at the input node (110s) and one of the one or more reference signals (R, R₁, . . . , R_{N}) generated by the reference circuit (130), the one or more response signals (RS, RS₁, . . . , RS_{N}) are associated with one or more features (F, F₁, . . . , F_{N}) of the input signal (S); an analysis circuit (120) coupled to the processing circuit (110) for analyzing the one or more response signals (RS, RS₁, . . . , RS_{N}) to generate one or more feature signals (FS, F₁S, . . . , F_{N}S) representing one or more feature values (FI, Feat) associated with one or more features (F, F₁, . . . , F_{N}) of the input signal; an output node (120o) to output the one or more feature signals (FS, F₁S, . . . , F_{N}S); and one or more processors (170) configured to classify the input signal (S) based on the one or more feature values represented by the one or more feature signals (FS, F₁S, . . . , F_{N}S). The recognition device may be further configured as described with reference to Examples 2 to 37.

In Example 42 is a feature extraction circuit (100) for analyzing an electric input signal for presence and/or absence of a feature, the feature extraction circuit (100) including: an input node to receive the electric input signal (S); a reference circuit (130) configured to generate an electric reference signal (R); a memristive structure (110e, 210m) configured to cause an electric response signal (RS) as a function of both the electric input signal (S) received at the input node and the electric reference signal (R) generated by the reference circuit (130); an electric analysis circuit (120) coupled to the memristive structure (110e, 210m) to determine a time integrated signal of the electric response signal (RS); and an output node to output the time integrated signal. The feature extraction circuit may be further configured as described with reference to Examples 2 to 37 specified for a use with electric signals.

In Example 51 is a classification device (300) for classifying an electric input signal, the classification device (300) including: an input node to receive the electric input signal (S); a reference circuit (130) configured to generate an electric reference signal (R); a memristive structure (110e, 210m) configured to cause an electric response signal (RS) as a function of both the electric input signal (S) received at the input node and the electric reference signal (R) generated by the reference circuit (130); an electric analysis circuit (120) coupled to the memristive structure (110e, 210m) to determine one or more characteristics of the electric response signal (RS) caused by the memristive structure (110e, 210m); and one or more processors (170) configured to determine a class (C) associated with the electric input signal (S) based on the one or more characteristics of the electric response signal (RS) determined by the electric analysis circuit (120).

In Example 52, the classification device (300) of Example 51 may optionally further include: a sensor signal input node to receive a sensor signal, and a mapping circuit (140) to modify the sensor signal to provide the electric input signal, wherein the electric input signal is in a predefined signal range (current and/or voltage range).

In Example 53, the classification device (300) of Example 51 or 52 may optionally further include that the one or more characteristics of the electric response signal (RS) includes a time integrated signal of the electric response signal (RS).

In Example 54, the classification device (300) of any one of Examples 51 to 53 may optionally further include that the memristive structure (110e, 210m) includes a first terminal and a second terminal, and that the classification device is configured to provide a first voltage at the first terminal as a function of the electric input signal received at the input node and to provide a second voltage at the second terminal as a function of the electric reference signal generated by the reference circuit.

In Example 55, the classification device (300) of Example 54 may optionally further include that the classification device is configured such that an electric current flows through the memristive structure and is generated by a time varying voltage difference between the first voltage provided at the first terminal and the second voltage provided at the second terminal.

In Example 56, the classification device (300) of any one of Examples 51 to 53 may optionally further include that the memristive structure includes a first terminal and a second terminal, and wherein the classification device is configured to provide a first time varying voltage at the first terminal as a function of both the electric input signal received at the input node and the reference signal generated by the reference circuit and, preferably, to provide a second voltage at the second terminal to bring the memristive structure into a predefined operation voltage range.

In Example 57, the classification device (300) of Example 56 may optionally further include that the classification device is configured such that a time varying electric current flows through the memristive structure and is generated by the first time varying voltage provided at the first terminal.

In Example 58, the classification device (300) of any one of Examples 51 to 53 may optionally further include that the memristive structure includes a first terminal and a second terminal, and wherein the recognition device is configured to provide a time varying electric current at the first terminal as a function of both the electric input signal received at the input node and the reference signal generated by the reference circuit and, preferably, to provide a second electric current at the second terminal to bring the memristive structure into a predefined operation range.

In Example 59, the classification device (300) of Example 58 may optionally further include that the classification device is configured such that a time varying electric voltage drops over the memristive structure and is generated by the time varying electric current.

In Example 60, the classification device (300) of any one of Examples 51 to 59 may optionally further include: a delay circuit configured to delay the electric input signal received at the input node and/or to delay the electric reference signal generated by the reference circuit.

In Example 61, the classification device (300) of Example 70 may optionally further include that the delay circuit is configured to synchronize the electric input signal and the electric reference signal with one another by delaying the electric input signal and/or the electric reference signal.

In Example 62, the classification device (300) of any one of Examples 51 to 61 may optionally further include: an event detector circuit configured to detect reception of the electric input signal at the input node and to modify and/or trigger the electric reference signal generated by the reference circuit based on the detected reception of the electric input signal.

In Example 63, the classification device (300) of any one of Examples 51 to 62 may optionally further include that the reference circuit is configured to generate the electric reference signal by branching and modifying the electric input signal.

In Example 64, the classification device (300) of any one of Examples 51 to 63 may optionally further include that the reference circuit is configured to generate the electric reference signal by branching and modifying the sensor signal.

In Example 65, the classification device (300) of Example 64 may optionally further include that modifying the electric input signal to generate the electric reference signal includes: delaying the electric input signal, and/or inverting the electric input signal, and/or clipping and/or amplifying the electric input signal, and/or changing an offset of the electric input signal, and/or amplifying the electric input signal with a time dependent amplification factor.

In Example 66, the classification device (300) of any one of Examples 51 to 65 may optionally further include that the electric reference signal is a class-specific electric reference signal of a corresponding class such that, in the case that the electric input signal belongs to the corresponding class, an electric current and/or volage caused by the memristive structure is characteristic for the corresponding class.

In Example 67, the classification device (300) of any one of Examples 51 to 66 may optionally further include that the electric analysis circuit includes an integrator to determine an analysis output representing a time integral of an electric current and/or a time integral of an electric volage as the one or more characteristics of the electric response signal (RS).

In Example 68, the classification device (300) of any one of Examples 51 to 67 may optionally further include that the electric analysis circuit includes a squaring circuit to determine an analysis output representing an absolute current flow or an absolute voltage as the one or more characteristics of the electric response signal (RS).

In Example 69, the classification device (300) of any one of Examples 51 to 68 may optionally further include that the electric analysis circuit includes an RMS-DC converter to output an analysis voltage representing the one or more characteristic of the electric current.

In Example 70, the classification device (300) of any one of Examples 51 to 69 may optionally further include that the one or more characteristics of the electric response signal (RS) includes one or more characteristic values that are in a predefined range in the case that the electric input signal belongs to a corresponding class and that are outside the predefined range in the case that the electric input signal does not belong to the corresponding class.

In Example 71, the classification device (300) of Example 70 may optionally further include that the one or more characteristic values are less than one or more corresponding threshold values in the case that the electric input signal belongs to the corresponding class and the one or more characteristic values are greater than the one or more corresponding threshold values in the case that the electric input signal does not belong to the corresponding class.

In Example 72, the classification device (300) of Example 70 or 71 may optionally further include that the one or more characteristic values are one or more voltage values representing an integral of the electric current during a predefined time interval and wherein the one or more corresponding threshold values are one or more corresponding threshold voltage values; and/or that the one or more characteristic values are one or more charge values representing an integral of the electric current during a predefined time interval and wherein the one or more corresponding threshold values are one or more corresponding threshold charge values; and/or that the one or more characteristic values are one or more average current values representing an average of the electric current during a predefined time interval and wherein the one or more corresponding threshold values are one or more corresponding threshold average current values.

In Example 73, the classification device (300) of any one of Examples 51 to 72 may optionally further include that the electric input signal received at the input node is a time dependent voltage signal and wherein the electric reference signal is a time dependent reference voltage signal.

In Example 74, the classification device (300) of any one of Examples 51 to 73 may optionally further include that the memristive structure has a non-linear current/voltage characteristic, preferably, the memristive structure has a transcendent current/voltage characteristic.

In Example 75, the classification device (300) of any one of Examples 51 to 74 may optionally further include that a waveform of the electric reference signal represents a neuro-signal associated with a class of neuro-signals or an electro-cardio-signal associated with a class of electro-cardio-signals.

In Example 76, the classification device (300) of any one of Examples 51 to 75 may optionally further include that the one or more processors are configured to determine the class associated with the electric input signal based on a clustering operation with the one or more characteristics of the electric response signal (RS) caused by the memristive structure as input for the clustering operation.

Example 81 is a classification device (300) for analyzing and classifying an electric input signal, the classification device (300) including: an input node to receive the electric input signal; a reference circuit configured to generate a first electric reference signal associated with a first class for classifying the electric input signal and a second electric reference signal associated with a second class for classifying the electric input signal; a first memristive structure configured to cause a first electric current as a function of both the electric input signal received at the input node and the first electric reference signal generated by the reference circuit; a second memristive structure configured to cause a second electric current as a function of both the electric input signal received at the input node and the second electric reference signal generated by the reference circuit; an electric analysis circuit coupled to the first memristive structure and to the second memristive structure and configured to determine one or more first characteristics of the first electric current and one or more second characteristics of the second electric current; and one or more processors configured to determine whether the first class or the second class is associated with the electric input signal based on a comparison of the one or more first characteristics of the first electric current and the one or more second characteristics of the second electric current with one another.

In Example 82, the classification device (300) of Example 81 may optionally further include that the first memristive structure includes a first terminal and a second terminal, and wherein the recognition device is configured to provide a first voltage at the first terminal of the first memristive structure as a function of the electric input signal received at the input node and to provide a second voltage at the second terminal of the first memristive structure as a function of the first electric reference signal generated by the reference circuit; and/or that the second memristive structure includes a first terminal and a second terminal, and wherein the recognition device is configured to provide a first voltage at the second terminal of the first memristive structure as a function of the electric input signal received at the input node and to provide a second voltage at the second terminal of the second memristive structure as a function of the second electric reference signal generated by the reference circuit. The classification device may be configured as described with reference to FIGS. 3A to 3C. The classification device may include a feature extraction circuit 100 in a configuration as described herein.

In Example 83, the classification device (300) of Example 81 may optionally further include that the first memristive structure includes a first terminal and a second terminal, and wherein the classification device is configured to provide a first voltage at the first terminal of the first memristive structure as a function of both the electric input signal received at the input node and the first reference signal generated by the reference circuit and to provide a second voltage at the second terminal of the first memristive structure to bring the first memristive structure into a predefined operation voltage range; and/or that the second memristive structure includes a first terminal and a second terminal, and wherein the classification device is configured to provide a first voltage at the first terminal of the second memristive structure as a function of both the electric input signal received at the input node and the second reference signal generated by the reference circuit and to provide a second voltage at the second terminal of the second memristive structure to bring the second memristive structure into a predefined operation voltage range.

In Example 84, the classification device (300) of Example 83 may optionally further include that the predefined operation voltage range of the first memristive structure is distinct from the predefined operation voltage range of the second memristive structure.

In Example 85, the classification device (300) of any one of Examples 82 to 84 may optionally further include that the classification device is configured such that the first electric current flows through the first memristive structure and is generated by a time dependent voltage difference between the first voltage provided at the first terminal of the first memristive structure and the second voltage provided at the second terminal of the first memristive structure; and/or that the classification device is configured such that the second electric current flows through the second memristive structure and is generated by a time dependent voltage difference between the first voltage provided at the first terminal of the second memristive structure and the second voltage provided at the second terminal of the second memristive structure.

In Example 86, the classification device (300) of any one of Examples 81 to 85 may optionally further include: a delay circuit configured to delay: the electric input signal received at the input node, and/or the first electric reference signal generated by the reference circuit, and/or the second electric reference signal generated by the reference circuit.

In Example 87, the classification device (300) of Example 86 may optionally further include that the delay circuit is configured to delay the first electric reference signal with a first delay and the second electric reference signal with a second delay different from the first delay.

In Example 88, the classification device (300) of Example 86 or 87 may optionally further include that the delay circuit is configured to synchronize the electric input signal and the first electric reference signal with one another by delaying the electric input signal and/or the first electric reference signal; and/or that the delay circuit is configured to synchronize the electric input signal and the second electric reference signal with one another by delaying the electric input signal and/or the second electric reference signal.

In Example 89, the classification device (300) of any one of Examples 81 to 88 may optionally further include: an event detector circuit configured to detect reception of the electric input signal at the input node and further configured to: modify and/or trigger the first electric reference signal generated by the reference circuit based on the detected reception of the electric input signal, and/or modify and/or trigger the second electric reference signal generated by the reference circuit based on the detected reception of the electric input signal.

In Example 90, the classification device (300) of any one of Examples 81 to 89 may optionally further include that the reference circuit is configured to generate the first electric reference signal and the second electric reference signal by branching and modifying the electric input signal.

In Example 91, the classification device (300) of Example 90 may optionally further include that the reference circuit is configured to modify the first electric reference signal based on a first modification and to modify the second electric reference signal based on a second modification different from the first modification.

In Example 92, the classification device (300) of Example 90 or 91 may optionally further include that modifying the electric input signal to generate the first electric reference signal and/or the second electric reference signal includes: delaying the electric input signal, and/or inverting the electric input signal, and/or clipping and/or amplifying the electric input signal, and/or changing an offset of the electric input signal, and/or amplifying the electric input signal with a time dependent amplification factor.

In Example 93, the classification device (300) of any one of Examples 81 to 92 may optionally further include that the first electric reference signal is a class-specific electric reference signal of the first class such that, in the case that the electric input signal belongs to the first class, the first electric current caused by the first memristive structure is characteristic for the first class; and/or that the second electric reference signal is a class-specific electric reference signal of the second class such that, in the case that the electric input signal belongs to the second class, the second electric current caused by the second memristive structure is characteristic for the second class.

In Example 94, the classification device (300) of any one of Examples 81 to 93 may optionally further include that the electric analysis circuit includes one or more current integrators to determine a first analysis output representing a time integral of the first electric current as the one or more first characteristics of the first electric current and to determine a second analysis output representing a time integral of the second electric current as the one or more second characteristics of the second electric current.

In Example 95, the classification device (300) of any one of Examples 81 to 94 may optionally further include that the electric analysis circuit includes a current squaring circuit to determine a first analysis output representing an absolute current flow of the first electric current as the one or more first characteristics of the first electric current and/or to determine a second analysis output representing an absolute current flow of the second electric current as the one or more second characteristics of the second electric current.

In Example 96, the classification device (300) of any one of Examples 81 to 95 may optionally further include that the electric analysis circuit includes an RMS-DC converter to output a first analysis voltage representing the one or more first characteristic of the first electric current and/or to output a second analysis voltage representing the one or more second characteristic of the second electric current.

In Example 97, the classification device (300) of any one of Examples 81 to 96 may optionally further include that the one or more first characteristics of the first electric current includes one or more first characteristic values that are in a first predefined range in the case that the electric input signal belongs to the first class and that are outside the first predefined range in the case that the electric input signal does not belong to the first class; and/or that the one or more second characteristics of the second electric current includes one or more second characteristic values that are in a second predefined range in the case that the electric input signal belongs to the second class and that are outside the second predefined range in the case that the electric input signal does not belong to the second class.

In Example 98, the classification device (300) of Example 97 may optionally further include that the one or more first characteristic values are less than one or more corresponding first threshold values in the case that the electric input signal belongs to the first class and the one or more first characteristic values are greater than the one or more corresponding threshold values in the case that the electric input signal does not belong to the corresponding class.

In Example 99, the classification device (300) of Example 97 or 98 may optionally further include that the one or more characteristic values are one or more voltage values representing an integral of the electric current during a predefined time interval and wherein the one or more corresponding threshold values are one or more corresponding threshold voltage values; and/or that the one or more characteristic values are one or more charge values representing an integral of the electric current during a predefined time interval and wherein the one or more corresponding threshold values are one or more corresponding threshold charge values; and/or that the one or more characteristic values are one or more average current values representing an average of the electric current during a predefined time interval and wherein the one or more corresponding threshold values are one or more corresponding threshold average current values.

In Example 100, the classification device (300) of any one of Examples 81 to 99 may optionally further include that the electric input signal received at the input node is a time dependent voltage signal and wherein the electric reference signal is a time dependent reference voltage signal.

In Example 101, the classification device (300) of any one of Examples 81 to 100 may optionally further include that the memristive structure has a non-linear current/voltage characteristic, preferably, the memristive structure has a transcendent current/voltage characteristic.

In Example 102, the classification device (300) of any one of Examples 81 to 101 may optionally further include that a waveform of the electric reference signal represents a neuro-signal associated with a class of neuro-signals or an electro-cardio-signal associated with a class of electro-cardio-signals.

In Example 103, the classification device (300) of any one of Examples 81 to 102 may optionally further include that the one or more processors are configured to determine the class associated with the electric input signal based on a clustering operation with the one or more characteristics of the electric response signal (RS) caused by the memristive structure as input for the clustering operation.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A feature extraction circuit comprising:
an input node to receive an input signal;
a reference circuit configured to generate one or more reference signals by branching the input signal and by modifying the branched input signal via one or more signal modifier elements;
a processing circuit configured to cause one or more response signals, each of the one or more response signals being a function of both the input signal received at the input node and one of the one or more reference signals generated by the reference circuit, the one or more response signals associated with one or more features of the input signal;
an analysis circuit coupled to the processing circuit for analyzing the one or more response signals to generate one or more feature signals representing one or more feature values associated with one or more features of the input signal; and
an output node configured to output the one or more feature signals.

2. The feature extraction circuit of claim 1, further comprising:
a sensor signal input node configured to receive a sensor signal, and a mapping circuit to modify the sensor signal to provide the input signal, wherein the input signal is in a predefined signal range for processing the input signal via the processing circuit.

3. The feature extraction circuit of claim 1,
wherein the analysis circuit comprises one or more time integration circuits and wherein the one or more feature signals are one or more time integration signals of the corresponding one or more response signals.

4. The feature extraction circuit of claim 1,
wherein the one or more feature values comprise integration values of one or more corresponding time integration signals determined from the corresponding one or more response signals at a predefined integration time.

5. The feature extraction circuit of claim 1,
wherein the one or more feature values comprise a first set of integration values of one or more corresponding time integration signals at a predefined first integration time and wherein the one or more feature values comprise a second set of integration values of one or more corresponding time integration signals at a predefined second integration time different from the first integration time; and/or
wherein the one or more feature values comprise one or more relative values and/or one or more dynamic values representing a change of the response signal in a predefined time.

6. The feature extraction circuit of claim 1,
wherein the analysis circuit is configured to generate the one or more feature signals to comprise a first set of feature values associated with positive signal portions of the input signal and a second set of feature values associated with negative signal portions of the input signal.

7. The feature extraction circuit of claim 1,
wherein the one or more signal modifier elements comprise one or more of the following group of signal modifier elements:
one or more time delay elements to provide one or more predefined signal time delays;
one or more offset elements to provide one or more predefined signal offsets;
one or more amplifier elements to provide one or more predefined signal amplifications;
one or more non-linear amplifier elements to provide one or more predefined non-linear signal amplifications;
one or more distortion elements to provide one or more predefined signal distortions;
one or more signal shape modifier elements to provide one or more predefined signal shape modifications;
one or more inverter elements to provide a predefined inverted signal; and/or
one or more clipping elements to provided a predefined clipped signal.

8. The feature extraction circuit of claim 1,
wherein the processing circuit comprises one or more processing elements, each of the one or more processing elements comprises at least two terminals, and wherein the processing circuit is configured to provide at least two voltages at the at least two terminals as a function of the input signal and a corresponding reference signal.

9. The feature extraction circuit of claim 1,
wherein the processing circuit comprises one or more processing elements configured to provide a non-linear current/voltage characteristics to generate the one or more response signals from the input signal and the corresponding one or more reference signals with the non-linear current/voltage characteristics.

10. The feature extraction circuit of claim 1,
wherein the analysis circuit comprises one or more analyzing elements configured to provide a non-linear current/voltage characteristics to generate the one or more feature signals from the corresponding one or more response signals with the non-linear current/voltage characteristics.

11. The feature extraction circuit of claim 1, further comprising:
an event detector circuit configured to detect reception of the input signal at the input node and to control an operation of the processing circuit, the analysis circuit, and/or the reference circuit based on a detected reception.

12. The feature extraction circuit of claim 1,
wherein the reference signal is a class-specific reference signal of a corresponding class such that, in the case that the input signal belongs to the corresponding class, the response signal and/or the feature signal are characteristic for the corresponding class.

13. The feature extraction circuit of claim 12,
wherein the feature values are within one or more predefined ranges in the case that the input signal is of an input signal type that belongs to a corresponding class;
wherein the feature values are outside the one or more predefined ranges in the case that the input signal is of an input signal type that does not belongs to a corresponding class;
wherein the feature values are outside the one or more predefined ranges in the case and are monitored in terms of signal fault detection; or
combinations thereof.

14. The feature extraction circuit of claim 1,
wherein the input signal received at the input node is a time dependent voltage signal and wherein the one or more reference signals are time dependent reference voltage signals; or
wherein the input signal received at the input node is a time dependent current signal and wherein the one or more reference signals are time dependent reference current signals.

15. The feature extraction circuit of claim 1, further comprising:
one or more processors configured to determine a class associated with the input signal based on the one or more feature signals;
wherein the class associated with the input signal is associated with a class-specific signal type of the input signal.

16. The feature extraction circuit of claim 15,
wherein the one or more processors are configured to determine the respective class associated with the input signal based on clustering the one or more feature values of the one or more feature signals in an n-dimensional feature space.

17. The feature extraction circuit of claim 1,
wherein the one or more signal modifier elements are one or more configurable signal modifier elements;
wherein the one or more configurable signal modifier elements are configured based on configuration data obtained from configuration measurements such that the one or more electric response signals associated with one or more class-specific features are distinct from one another; and/or
wherein the one or more configurable signal modifier elements are configured based on configuration data obtained from configuration measurements such that a recognition rate of a recognition algorithm based on the one or more features is in a predefined range.

18. The feature extraction circuit of claim 1,
wherein the analysis circuit and/or the one or more processors are configured to check whether the one or more feature values are within one or more class specific feature value ranges.

19. A classification device for classifying an electric input signal, the classification device comprising:
an input node to receive the electric input signal;
a reference circuit configured to generate an electric reference signal;
a memristive structure configured to cause an electric response signal as a function of both the electric input signal received at the input node and the electric reference signal generated by the reference circuit;
an electric analysis circuit coupled to the memristive structure to determine one or more characteristics of the electric response signal caused by the memristive structure; and
one or more processors configured to determine a class associated with the electric input signal based on the one or more characteristics of the electric response signal determined by the electric analysis circuit.

20. A classification device for analyzing and classifying an electric input signal, the classification device comprising:
an input node to receive the electric input signal;
a reference circuit configured to generate a first electric reference signal associated with a first class for classifying the electric input signal and a second electric reference signal associated with a second class for classifying the electric input signal;
a first memristive structure configured to cause a first electric current as a function of both the electric input signal received at the input node and the first electric reference signal generated by the reference circuit;
a second memristive structure configured to cause a second electric current as a function of both the electric input signal received at the input node and the second electric reference signal generated by the reference circuit;
an electric analysis circuit coupled to the first memristive structure and to the second memristive structure and configured to determine one or more first characteristics of the first electric current and one or more second characteristics of the second electric current; and
one or more processors configured to determine whether the first class or the second class is associated with the electric input signal based on a comparison of the one or more first characteristics of the first electric current and the one or more second characteristics of the second electric current with one another.
